(19) United States
(12) Patent Application Publication
(10) Pub. No.: US 2014/0353624 A1
(43) Pub. Date: Dec. 4, 2014

(54) ORGANIC LIGHT-EMITTING DIODE

(71) Applicants: Seul-Ong KIM, Yongin-City (KR); Dong-Woo SHIN, Yongin-City (KR)

(72) Inventors: Seul-Ong KIM, Yongin-City (KR); Dong-Woo SHIN, Yongin-City (KR)

(21) Appl. No.: 14/102,810

(22) Filed: Dec. 11, 2013

(30) Foreign Application Priority Data
May 29, 2013 (KR) 10-2013-0061259

(51) Int. Cl. H01L 51/50; H01L 51/00

(52) U.S. Cl. CPC H01L 51/5016; H01L 51/0052; H01L 51/0072
USPC 257/40

(57) ABSTRACT

An organic light-emitting diode including a first electrode; a second electrode facing the first electrode; an emission layer between the first electrode and the second electrode, the emission layer including a host and a dopant; a first hole transport layer between the first electrode and the emission layer; and a second hole transport layer between the first hole transport layer and the emission layer, wherein the first hole transport layer includes a first carbazole-based compound and a p-dopant, the second hole transport layer includes a second carbazole-based compound and does not comprise the p-dopant, the host of the emission layer includes a third carbazole-based compound, the dopant of the emission layer includes a phosphorescent metal complex, and the first carbazole-based compound, the second carbazole-based compound, and the third carbazole-based compound are all different from each other.

### CROSS-REFERENCE TO RELATED APPLICATION

Korean Patent Application No. 10-2013-0061259, filed on May 29, 2013, in the Korean Intellectual Property Office, and entitled: “Organic Light Emitting Diode,” is incorporated by reference herein in its entirety.

### BACKGROUND

1. Field

Embodiments relate to an organic light-emitting diode.

2. Description of the Related Art

Organic light-emitting diodes (OLEDs), which are self-emitting diodes, have advantages such as wide viewing angles, excellent contrast, quick responses, high brightness, excellent driving voltage characteristics, and can provide full color images.

An OLED may have a structure including an anode, a hole transport layer, an emission layer, an electron transport layer, and a cathode sequentially stacked in this order on a substrate. The hole transport layer, the emission layer, and the electron transport layer may be organic thin films formed of organic compounds.

An operating principle of an OLED having the above-described structure may be as follows:

When a voltage is applied between the anode and the cathode, holes injected from the anode may move to the emission layer via the hole transport layer, and electrons injected from the cathode may move to the emission layer via the electron transport layer. The holes and electrons (carriers) may recombine in the organic emission layer to generate excitons. When the excitons drop from an excited state to a ground state, light is emitted.

### SUMMARY

Embodiments are directed to an organic light-emitting diode.

The embodiments may be realized by providing an organic light-emitting diode including a first electrode; a second electrode facing the first electrode; an emission layer between the first electrode and the second electrode, the emission layer including a host and a dopant; a first hole transport layer between the first electrode and the emission layer; and a second hole transport layer between the first hole transport layer and the emission layer, wherein the first hole transport layer includes a first carbazole-based compound and a p-dopant, the second hole transport layer includes a second carbazole-based compound and does not include the p-dopant, the host of the emission layer includes a third carbazole-based compound, the dopant of the emission layer includes a phosphorescent metal complex, and the first carbazole-based compound, the second carbazole-based compound, and the third carbazole-based compound are all different from each other.

The first hole transport layer may directly contact the second hole transport layer, and the second hole transport layer may directly contact the emission layer.

A weight ratio of the p-dopant to the first carbazole-based compound may be about 0.1:99.9 to about 20:80.

A hole mobility of the first carbazole-based compound may be greater than a hole mobility of the second carbazole-based compound.

A difference between a HOMO level of the first hole transport layer and a HOMO level of the second hole transport layer may be less than about 0.3 eV.

A triplet energy of the second carbazole-based compound of the second hole transport layer may be greater than a triplet energy of the phosphorescent metal complex of the emission layer.

A molecular weight of the third carbazole-based compound of the emission layer may be about 400 g/mol or higher.

The phosphorescent metal complex of the emission layer may have a maximum phosphorescent emission peak wavelength of about 480 nm to about 650 nm.

The first carbazole-based compound may be represented by Formula 1, below, the second carbazole-based compound may be represented by Formula 2, below, and the third carbazole-based compound may be represented by Formula 3, below:

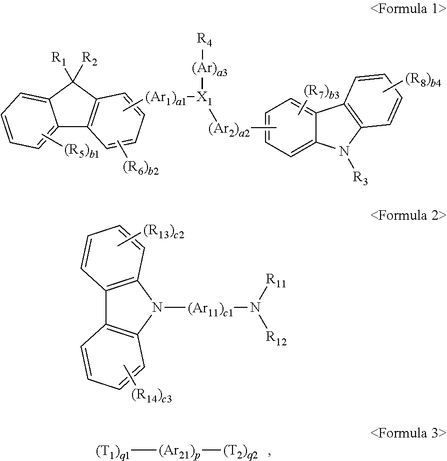

wherein, in Formulae 1 to 3, X₁ may be selected from N, B, or P; Ar₁ to Ar₃,

Ar₁₁, and Ar₂₁ may be each independently selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, or a substituted or unsubstituted C₂-C₆₀ heteroarylene group; a1 to a3 and p may be each independently an integer of 0 to 5; c1 may be an integer of 1 to 5; p may be an integer of 0 to 5; R₁, R₂, R₄ to R₈, R₁₃, and R₁₄ may be each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁)(Q₂), or —Si(Q₃)(Q₄)(Q₅), wherein Q₁ to Q₅ are each independently selected from a C₁-C₆₀ alkyl group, a C₁-C₆₀ alkoxy group, a C₆-C₆₀ aryl group, or a C₂-C₆₀ heteroaryl group; R₃, R₁₁, and R₁₂ may be each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, or —Si(Q₃)(Q₄)(Q₅), wherein Q₃ to Q₅ are each independently selected from a C₁-C₆₀ alkyl group, a C₁-C₆₀ alkoxy group, a C₆-C₆₀ aryl group, or a C₂-C₆₀ heteroaryl group; b1, b4, c2, and c3 may be each independently an integer of 1 to 4; b2 and b3 may be each independently an integer of 1 to 3; T₁ may be selected from a substituted or unsubstituted a carbazolyl group, a substituted or unsubstituted azacarbazolyl group, or a substituted or unsubstituted condensed carbazolyl group; T₂ may be an N-containing cyclic group; and q1 and q2 may be each independently an integer of 1 to 5.

Ar₁ to Ar₃, Ar₁₁, and Ar₂₁ in Formulae 1 to 3 may be each independently represented by one of Formulae 10-1 to 10-24 below:

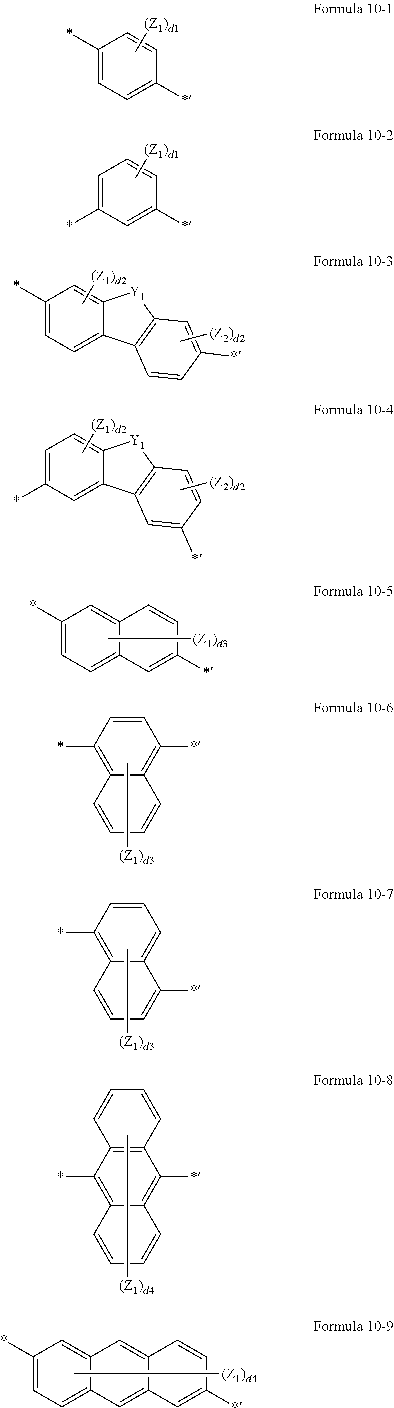

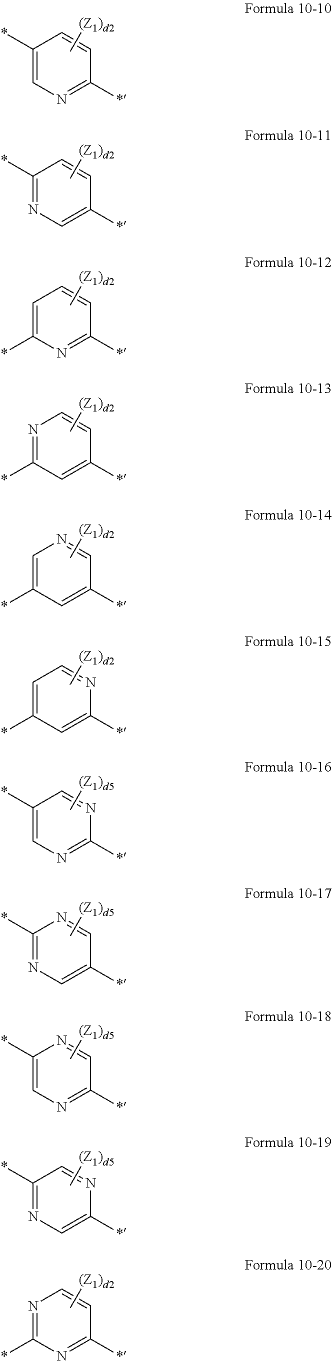

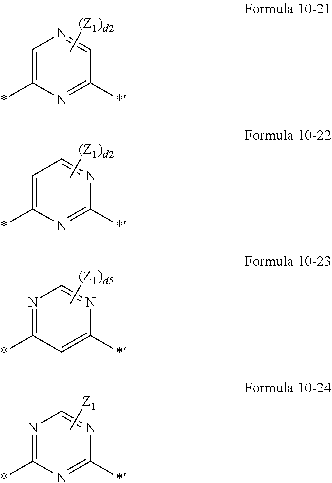

wherein, in Formulae 10-1 to 10-24, Y₁ may be O, S, C(R₂₁)(R₂₂), or N(R₂₃); Z₁, Z₂, and R₂₁ to R₂₃ may be each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, and a C₁-C₂₀ alkoxy group; a C₁-C₂₀ alkyl group and a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof; a C₆-C₂₀ aryl group or a C₂-C₂₀ heteroaryl group; a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or —N(Q₁₁)(Q₁₂) or —Si(Q₁₃)(Q₁₄)(Q₁₅), wherein Q₁₁ to Q₁₅ are each independently a C₁-C₂₀ alkyl group, a C₁-C₂₀ alkoxy group, a C₆-C₂₀ aryl group, or a C₂-C₂₀ heteroaryl group, d1 may be an integer of 1 to 4; d2 may be an integer of 1 to 3; d3 may be an integer of 1 to 6; d4 may be an integer of 1 to 8; and d5 may be 1 or 2.

Ar₁ to Ar₃, Ar₁₁, and Ar₂₁ in Formulae 1 to 3 may be each independently represented by one of Formulae 11-1 to 11-11, below:

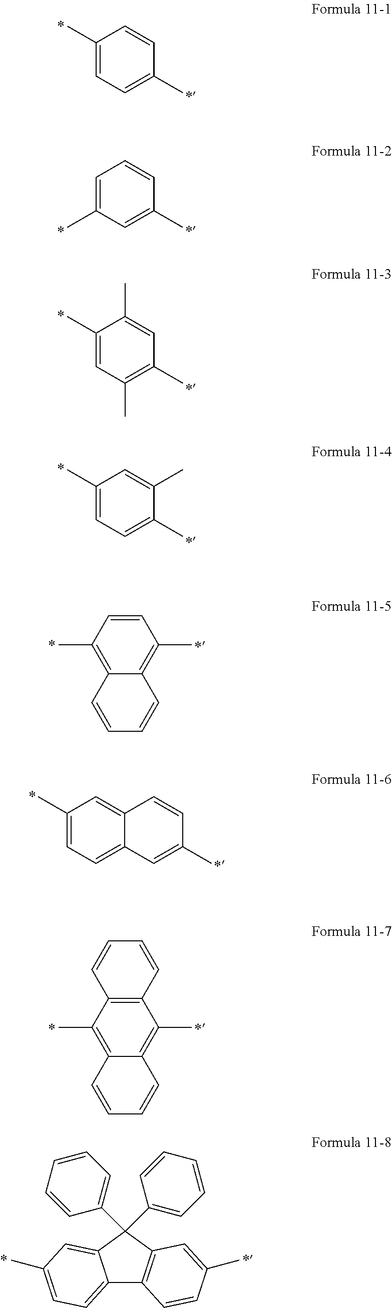

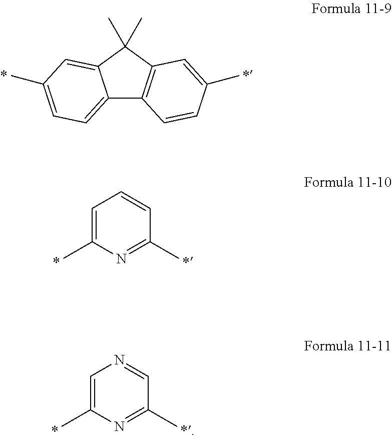

In Formula 1 i) a1 may be 0 and a2 may be 0; ii) a1 may be 1 and a2 may be 0; iii) a1 may be 2 and a2 may be 0; iv) a1 may be 0 and a2 may be 1; v) a1 may be 0 and a2 may be 2; or vi) a1 may be 1 and a2 may be 1; in Formula 2, c1 may be 1, 2, or 3; and in Formula 3, p may be 0, 1, 2, or 3.

R₃ to R₈ and R₁₁ to R₁₄ in Formulae 1 and 2 may be each independently represented by one of Formulae 12-1 to 12-22 below:

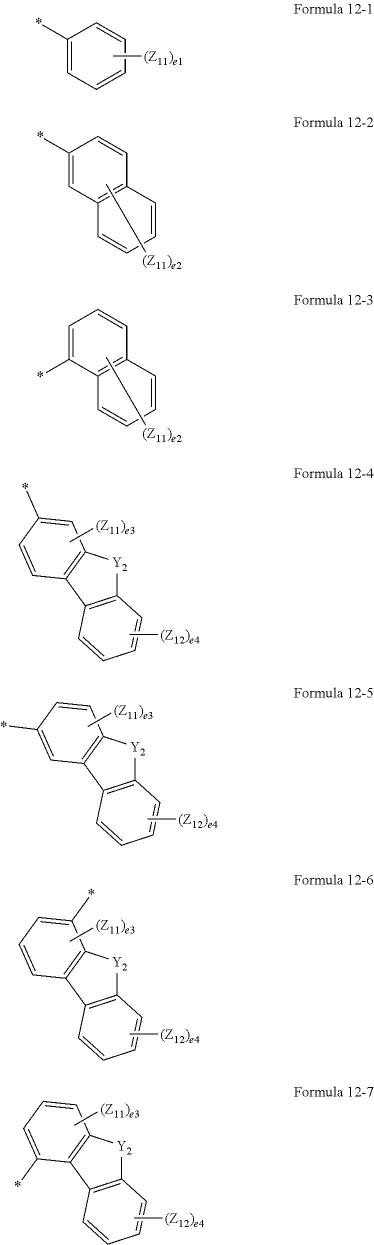

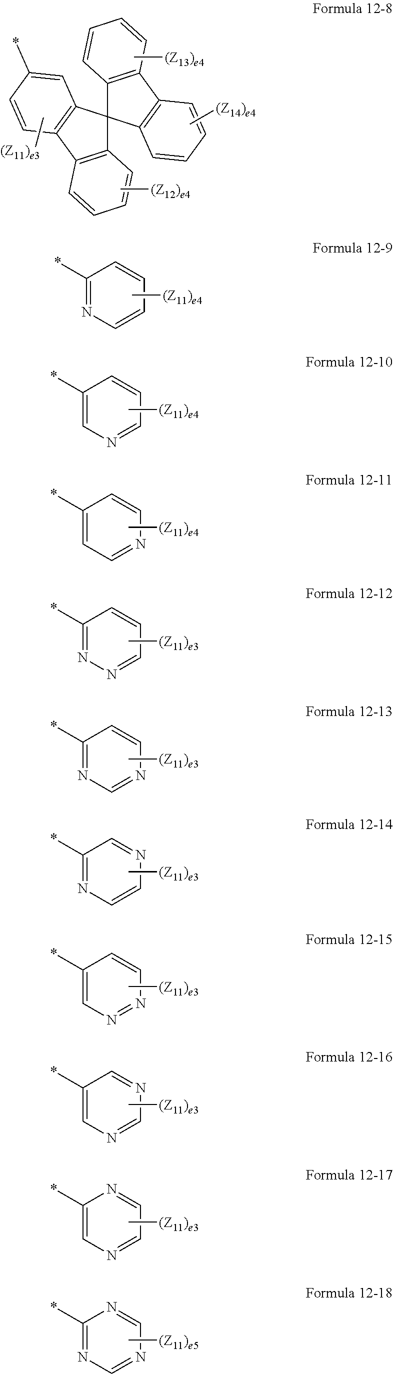

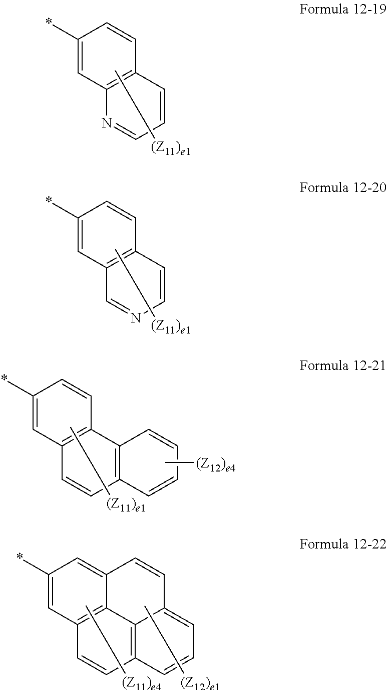

in Formulae 12-1 to 12-22 Y₂ and Y₃ may be each independently selected from O, S, C(R₂₅)(R₂₆), or N(R₂₇); Z₁₁ to Z₁₄ and R₂₅ to R₂₇ may be each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group; a C₁-C₂₀ alkyl group or a C₁-C₂₀ alkoxy group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof; a C₆-C₂₀ aryl group or a C₂-C₂₀ heteroaryl group; a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or —N(Q₁₁)(Q₁₂) or —Si(Q₁₃)(Q₁₄)(Q₁₅), wherein Q₁₁ to Q₁₅ are each independently selected from a C₁-C₂₀ alkyl group, a C₁-C₂₀ alkoxy group, a C₆-C₂₀ aryl group, or a C₂-C₂₀ heteroaryl group; e1 may be an integer of 1 to 5; e2 may be an integer of 1 to 7; e3 may be an integer of 1 to 3; e4 may be an integer of 1 to 4; and e5 may be 1 or 2.

R₃ to R₈ and R₁₁ to R₁₄ in Formulae 1 and 2 may be each independently represented by one of Formulae 13-1 to 13-19 below:

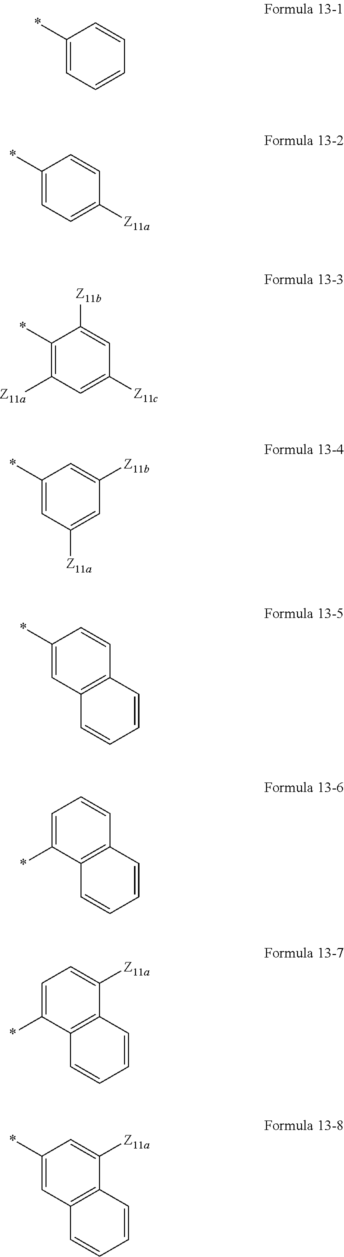

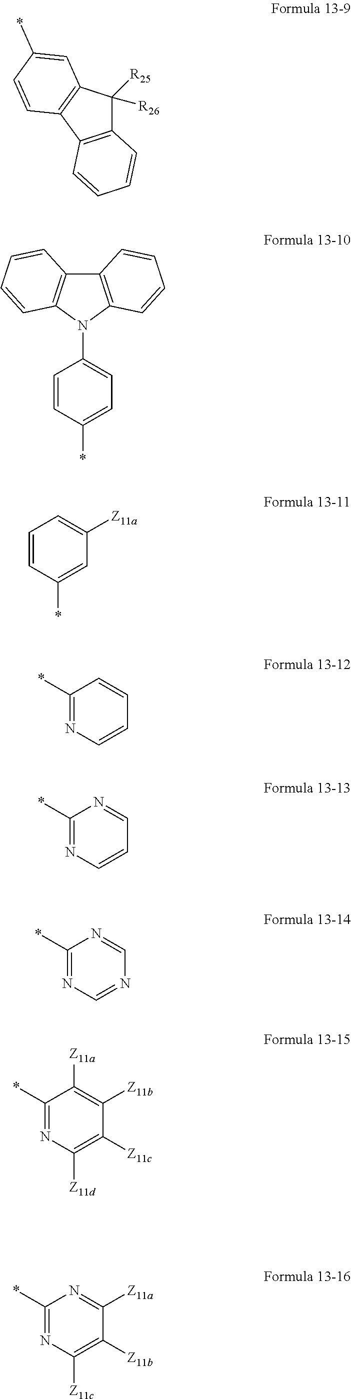

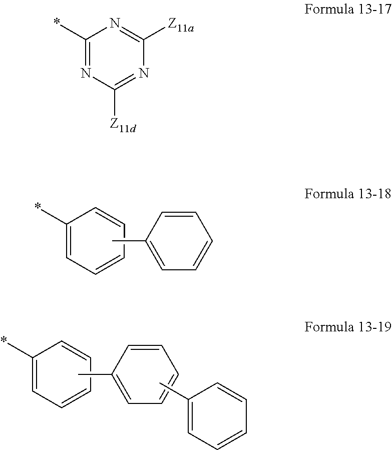

wherein Z₁₁ₐ to Z_{11d}, R₂₅ and R₂₆ in Formulae 13-1 to 13-19 may be each independently selected from a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group; a C₁-C₂₀ alkyl group or a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof; a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group; or a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

R₁ to R₂ in Formula 1 may be each independently selected from a C₁-C₂₀ alkyl group; a C₁-C₂₀ alkyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof; a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group; or a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

The first carbazole-based compound represented by Formula 1 may be represented by Formula 1A(1) or 1B(1) below:

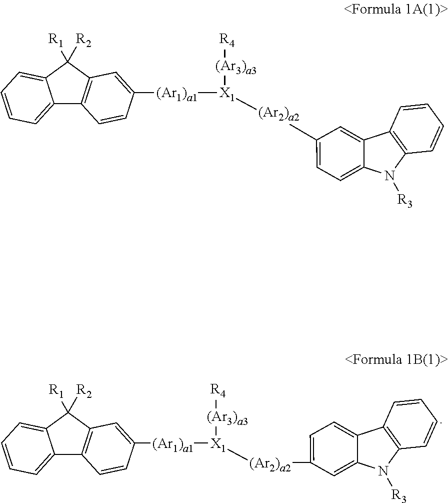

T₁ in Formula 3 may be selected from a carbazolyl group, an azacarbazolyl group, a benzocarbazolyl group, a naphthocarbazolyl group, or an indolocarbazolyl group; or a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁₁)(Q₁₂), or —Si(Q₁₃)(Q₁₄)(Q₁₅), wherein Q₁₁ to Q₁₅ are each independently selected from a C₁-C₆₀ alkyl group, a C₁-C₆₀ alkoxy group, a C₆-C₆₀ aryl group, and a C₂-C₆₀ heteroaryl group, and T₂ in Formula 3 may be selected from an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group; or an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁)(Q₂), or —Si(Q₃)(Q₄)(Q₅), wherein Q₁ to Q₅ are each independently a C₁-C₆₀ alkyl group, a C₁-C₆₀ alkoxy group, a C₆-C₆₀ aryl group, or a C₂-C₆₀ heteroaryl group).

T₁ in Formula 3 may be selected from a carbazolyl group, an azacarbazolyl group, a benzocarbazolyl group, a naphthocarbazolyl group, or an indolocarbazolyl group; or a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

T₂ in Formula 3 may be selected from an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group; or an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

### BRIEF DESCRIPTION OF THE DRAWINGS

Features will be apparent to those of skill in the art by describing in detail exemplary embodiments with reference to the attached drawings in which:

FIG. 1 illustrates a schematic view of a structure of an organic light-emitting diode according to an embodiment; and

FIG. 2 illustrates an energy diagram of a first carbazole-based compound, a second carbazole-based compound, a third carbazole-based compound, and a phosphorescent metal complex.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” may include any and all combinations of one or more of the associated listed items. Expressions such as “at least one of,” when preceding a list of elements, modify the entire list of elements and do not modify the individual elements of the list.

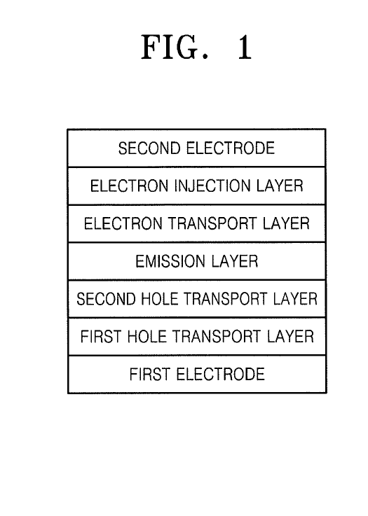

FIG. 1 illustrates a view of an organic light-emitting diode including a first electrode, a first hole transport layer, a second hole transport layer, an emission layer, an electron transport layer, an electron injection layer, and a second electrode, which are sequentially stacked in this stated order.

In FIG. 1, the first electrode may act as an anode to or from which holes are injected and the second electrode acts as a cathode to or from which electrons are injected.

Although not illustrated in FIG. 1, a substrate may be further provided under the first electrode or above the second electrode. When the substrate is above the second electrode, the organic light-emitting diode of FIG. 1 may be an inverted-type organic light-emitting diode.

For use as the substrate, a suitable substrate for an organic light-emitting diode may be used. For example, the substrate may be a glass substrate or a transparent plastic substrate with excellent mechanical strength, thermal stability, transparency, surface smoothness, ease of handling, and water resistance.

When a substrate is provided under the first electrode, the first electrode may be formed by providing a material for the first electrode by deposition or sputtering. The first electrode material may be selected from materials that have high work function to allow holes to be easily injected thereinto or therefrom.

The first electrode may be a reflective electrode, a semi-transmissive electrode, or a transmissive electrode. When a substrate is disposed under the first electrode and the first electrode is a reflective electrode, the organic light-emitting diode of FIG. 1 may be a top emission-type organic light-emitting diode, and when a substrate is disposed under the first electrode and the first electrode is a semi-transmissive electrode or a transmissive electrode, the organic light-emitting diode of FIG. 1 may be a bottom emission-type or dual-emission type organic light-emitting diode.

A material for the first electrode may be a transparent material with high conductivity. Examples of such a material may include indium tin oxide (ITO), indium zinc oxide (IZO), tin oxide (SnO₂), and zinc oxide (ZnO). According to some embodiments, the material for the second electrode may include, e.g., magnesium (Mg), aluminum (Al), aluminum (Al)-lithium (Li), calcium (Ca), magnesium (Mg)-indium (In), magnesium (Mg)-silver (Ag), or the like.

The first electrode may be a single- or multi-layered structure. For example, the first electrode may have a three-layered structure of ITO/Ag/ITO.

Also, the second electrode may face the first electrode. A material for forming the second electrode may include, e.g., metal, alloy, an electrically conductive compound, or a combination thereof, each of which has a low work function. For example, the material for forming the second electrode may include lithium (Li), magnesium (Mg), aluminum (Al), aluminum-lithium (Al—Li), calcium (Ca), magnesium-indium (Mg—In), or magnesium-silver (Mg—Ag). In an implementation, to manufacture a top-emission light-emitting diode, indium tin oxide (ITO) or indium zinc oxide (IZO) may be used to form a transmissive second electrode.

The emission layer may be disposed between the first electrode and the second electrode, the first hole transport layer may be disposed between the first electrode and the emission layer, and the second hole transport layer may be disposed between the first hole transport layer and the emission layer.

The electron transport layer and the electron injection layer may be sequentially disposed between the emission layer and the second electrode.

In the organic light-emitting diode of FIG. 1, holes may be provided through or from the first electrode and may move toward the emission layer through the first hole transport layer and the second hole transport layer. Electrons may be provided through or from the second electrode and may move toward the emission layer through the electron injection layer and the electron transport layer. The holes and electrons arriving at the emission layer may be recombined with each other in the emission layer to generate excitons. The excitons may change from an excited state to a ground state, thereby generating light.

In the organic light-emitting diode of FIG. 1, the first hole transport layer may directly contact the second hole transport layer, and the second hole transport layer may directly contact the emission layer.

Although not illustrated in FIG. 1, a hole injection layer may be additionally included between the first electrode and the first hole transport layer.

The hole injection layer may be formed on the first electrode by using various methods, e.g., vacuum deposition, spin coating, casting, LB deposition, or the like.

When the hole injection layer is formed using vacuum deposition, vacuum deposition conditions may vary according to the compound that is used to form the hole injection layer, and the desired structure and thermal properties of the hole injection layer to be formed. For example, vacuum deposition may be performed at a temperature of about 100° C. to about 500° C., a pressure of about 10⁻⁸ torr to about 10³ torr, and a deposition rate of about 0.01 to about 100 Å/sec. However, the deposition conditions are not limited thereto.

When a hole injection layer is formed using spin coating, the coating conditions may vary according to the compound that is used to form the hole injection layer, and the desired structure and thermal properties of the hole injection layer to be formed. For example, the coating rate may be in the range of about 2,000 rpm to about 5,000 rpm, and a temperature at which heat treatment is performed to remove a solvent after coating may be in the range of about 80° C. to about 200° C. However, the coating conditions are not limited thereto.

A material for forming the hole injection layer may include, e.g., N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, a polyaniline/dodecylbenzenesulfonic acid (pani/DBSA), poly(3,4-ethylenedioxythiophene)/poly(4-styrenesulfonate) (PEDOT/PSS), polyaniline/camphor sulfonicacid (pani/CSA), or (polyaniline)/poly(4-styrenesulfonate) (PANI/PSS).

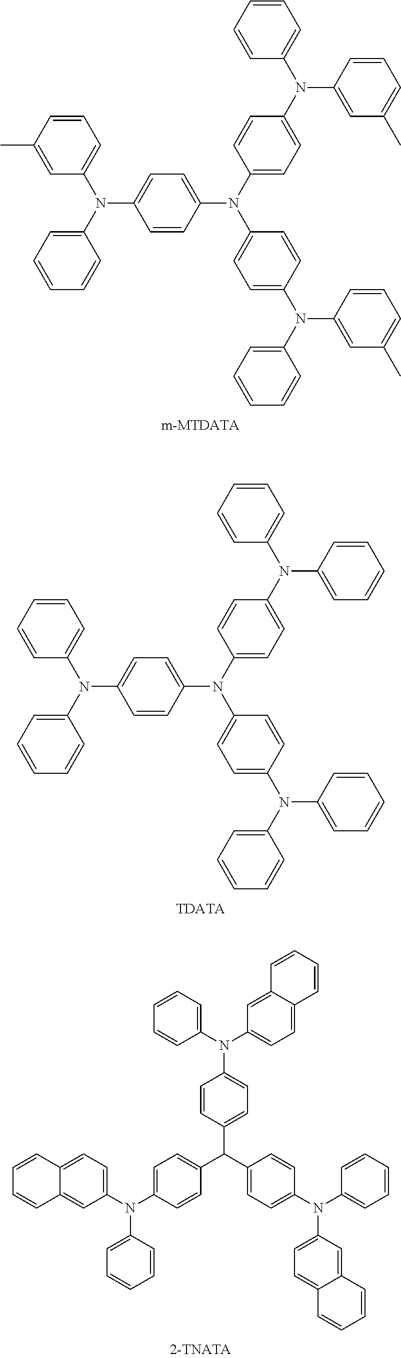

A thickness of the hole injection layer may be in a range of about 100 Å to about 10,000 Å, e.g., about 100 Å to about 1,000 Å. When the thickness of the hole injection layer is within these ranges, the hole injection layer may have satisfactory hole injection ability without a substantial increase in driving voltage.

Then, the first hole transport layer, the second hole transport layer, and the emission layer may be sequentially formed on the first electrode (when a hole injection layer is formed, on the hole injection layer) by using various methods including, e.g., a vacuum deposition method, a spin coating method, a casting method, or an LB method. When the first hole transport layer, the second hole transport layer, and the emission layer are formed using vacuum deposition or spin coating, the deposition and coating conditions may be similar to those for the formation of the hole injection layer, though the conditions for deposition and coating may vary according to the material that is used to form the hole transport layer.

The first hole transport layer may include a first carbazole-based compound and a p-dopant.

The second hole transport layer may include a second carbazole-based compound and may not include the p-dopant (included in the first hole transport layer).

The emission layer may include a host and a dopant, and the host of the emission layer may include a third carbazole-based compound and the dopant of the emission layer may include a phosphorescent metal complex.

The term “carbazole-based compound” used herein may refer to a compound that has at least one of carbazole or carbazole derivatives as a terminal group and/or a linking group thereof. Examples of the carbazole derivatives may include a carbazole in which at least one ring forming carbon atoms is substituted with nitrogen (e.g., azacarbazole, or the like) and a condensed carbazole fused with other rings (e.g., benzocarbazole, naphthocarbazole, dibenzocarbazole, indolocarbazole, or the like).

In an implementation, the carbazole and carbazole derivatives may be substituted with the following substituents (e.g., R₁, R₂, R₅, and R₆ of Formula 1 below, R₁₃ and R₁₄ of Formula 2 below, and T₁ of Formula 3 below).

Each of the first carbazole-based compound included in the first hole transport layer, the second carbazole-based compound included in the second hole transport layer, and the third carbazole-based compound included as a host in the emission layer may include at least one of the carbazole or carbazole derivatives. Accordingly, when an organic light-emitting diode is driven, deterioration at an interface between the first hole transport layer and the second hole transport layer and deterioration at an interface between the second hole transport layer and the emission layer may be minimized. Thus, stability of the organic light-emitting diode and lifespan characteristics may be improved.

Each of the first carbazole-based compound, the second carbazole-based compound, and the third carbazole-based compound may include at least one of the carbazole and the carbazole derivatives. The first carbazole-based compound, the second carbazole-based compound, and the third carbazole-based compound may differ from each other.

A weight ratio of the p-dopant to the first carbazole-based compound in the first hole transport layer may be in a range of about 0.1:99.9 to about 20:80, e.g., about 0.5:99.5 to about 15:85. When a weight ratio of the p-dopant to the first carbazole-based compound in the first hole transport layer is within these ranges, excess hole supply from the first electrode to the emission layer may be reduced and/or prevented, thereby improving lifespan characteristics of an organic light-emitting diode.

The p-dopant included in the first hole transport layer may be selected from materials that promote the transportation of holes.

For example, the p-dopant may include at least one selected from quinone derivatives, metal oxides, or cyano-containing compounds, but the p-dopant is not limited thereto. Examples of the p-dopant may include quinone derivatives, such as tetracyanoquinonedimethane (TCNQ) or 2,3,5,6-tetrafluoro-tetracyano-1,4-benzoquinonedimethane (F4-TCNQ); metal oxides, such as tungsten oxide or molybdenum oxide; and a cyano-containing compound, such as Compound 200 below.

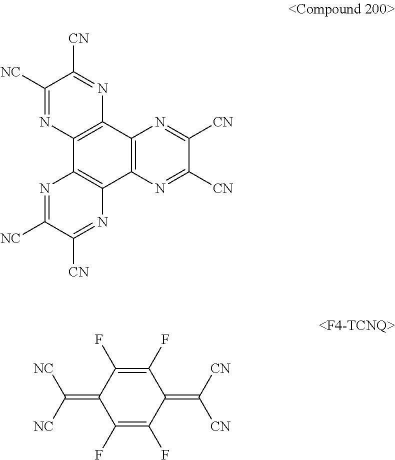 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

The second hole transport layer may include the second carbazole-based compound and may not include the p-dopant (that is included in the first hole transport layer). By doing so, a supply of holes from the first electrode to the second hole transport layer may be promoted while an increase in driving voltage may be prevented.

For example, the second hole transport layer may be formed of the second carbazole-based compound.

Hole mobility of the first carbazole-based compound (included in the first hole transport layer) may be greater than hole mobility of the second carbazole-based compound (included in the second hole transport layer). Herein, the hole mobility of the first carbazole-based compound (included in the first hole transport layer) and the hole mobility of the second carbazole-based compound (included in the second hole transport layer) may be measured under the same conditions (e.g., the same electric field conditions) by using the same methods. By doing so, the supply of holes from the first electrode to the second hole transport layer through the first hole transport layer may be promoted, transportation of holes and electrons between the first electrode and the second electrode of the organic light-emitting diode may be balanced, and an emission region may be effectively fixed on the emission layer. Also, arrival of excess holes at the emission layer to reach either an interface between the emission layer and the electron transport layer or the electron transport layer may be prevented. Accordingly, even when a separate hole blocking layer is not formed between the emission layer and the electron transport layer, the emission region may be effectively fixed inside the emission layer. Accordingly, in the organic light-emitting diode, the emission layer may directly contact the electron transport layer.

In the organic light-emitting diode of FIG. 1, a difference between a HOMO level of the first hole transport layer and a HOMO level of the second hole transport layer may be less than about 0.3 eV, e.g., less than about 0.2 eV or less than about 0.1 eV. Therefore, holes may move smoothly from the first hole transport layer to the second hole transport layer. Thus, a driving voltage of the organic light-emitting diode may decrease.

The dopant included in the emission layer may include a phosphorescent metal complex. A triplet energy of the second carbazole-based compound of the second hole transport layer may be greater than a triplet energy of the phosphorescent metal complex in the emission layer. By doing so, triplet excitons of the phosphorescent metal complex included in the emission layer may be efficiently confined within the emission layer. Thus, stability of the organic light-emitting diode may improve.

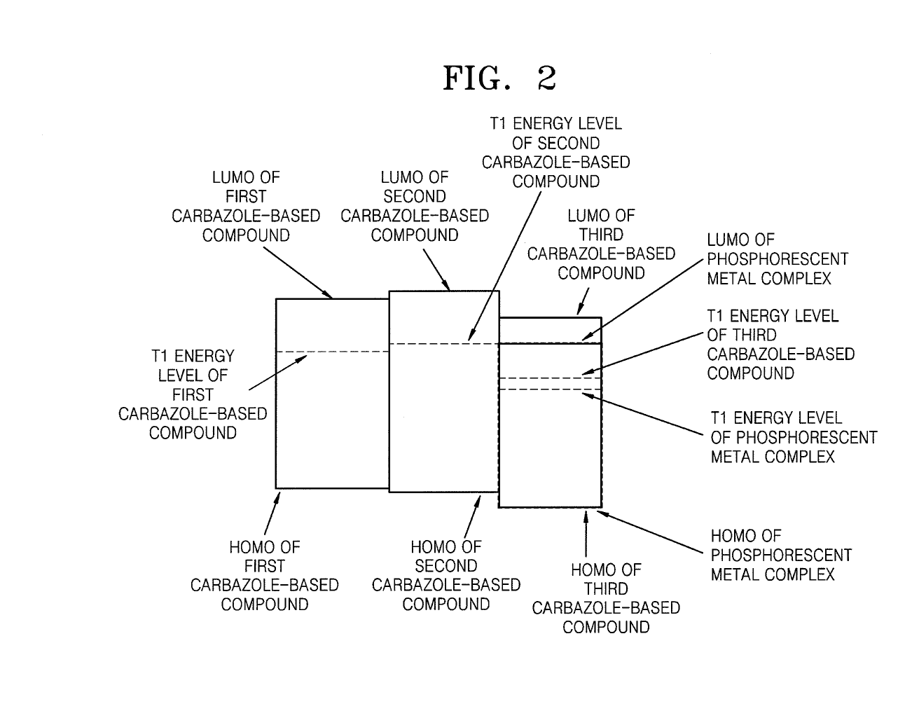

FIG. 2 illustrates an energy diagram of the first carbazole-based compound, the second carbazole-based compound, the third carbazole-based compound, and the phosphorescent metal complex.

In FIG. 2, a difference (D) between a HOMO level of the first carbazole-based compound and a HOMO level of the second carbazole-based compound may be less than about 0.3 eV.

Also, in FIG. 2, a triplet energy level of the second carbazole-based compound of the second hole transport layer may be greater than a triplet energy level of the phosphorescent metal complex in the emission layer.

In the emission layer of FIG. 2, a triplet energy level of the phosphorescent metal complex may be greater than a triplet energy (A) of the second carbazole-based compound of the second hole transport layer. Thus, a triplet energy (B) of the phosphorescent metal complex of the emission layer may be transitioned to the second hole transport layer, thereby leading to a decrease in luminescence efficiency of the organic light-emitting diode of FIG. 1.

However, the organic light-emitting diode of FIG. 1 may be constructed such that, as illustrated in FIG. 2, the triplet energy level of the second carbazole-based compound of the second hole transport layer may be greater than the triplet energy level of the phosphorescent metal complex of the emission layer. Thus, the triplet energy level of the phosphorescent metal complex of the emission layer may not be transitioned to the second hole transport layer, and excitons may be effectively produced in the emission layer, and thus, luminescent efficiency may be maximized.

A molecular weight of the third carbazole-based compound included in the emission layer may be about 400 g/mol or more, e.g., in a range of about 400 g/mol to about 1,200 g/mol. Within this range of the molecular weight of the third carbazole-based compound included in the emission layer, when the third carbazole-based compound is deposited to form an emission layer, a stable deposition speed and a stable deposition temperature may be obtained.

The phosphorescent metal complex included in the dopant of the emission layer may have a maximum phosphorescent emission peak wavelength of about 480 nm to about 650 nm. Accordingly, the phosphorescent metal complex may emit red light, green light, or blue light.

When the maximum phosphorescent emission peak wavelength range of the phosphorescent metal complex is within this range, the triplet energy of the phosphorescent metal complex may be smaller than the triplet energy of the second hole transport layer to help prevent extinction caused by the second hole transport layer. Accordingly, luminescent efficiency of the organic light-emitting diode may improve. Also, the maximum phosphorescent emission peak wavelength may not include an unnecessary long wavelength range. Thus, a decrease in efficiency and a decrease in lifespan due to emission of unnecessary color of light may be prevented. An optimal emission peak wavelength of red light in a currently available color coordinate may be about 620 nm.

The phosphorescent metal complex may be selected from suitable complexes that satisfy the triplet energy level range and the maximum phosphorescent emission peak wavelength range.

The dopant included in the emission layer may be a suitable dopant.

For example, the blue phosphorescent metal complex may be selected from the following compounds:

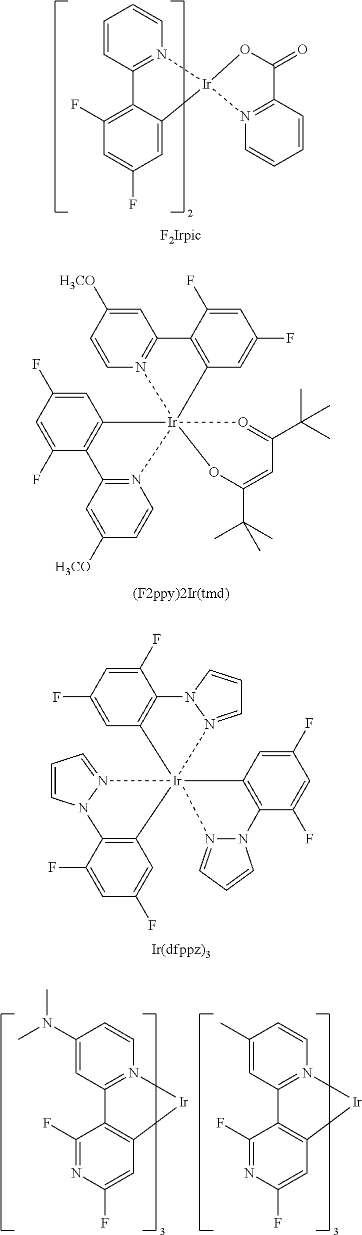

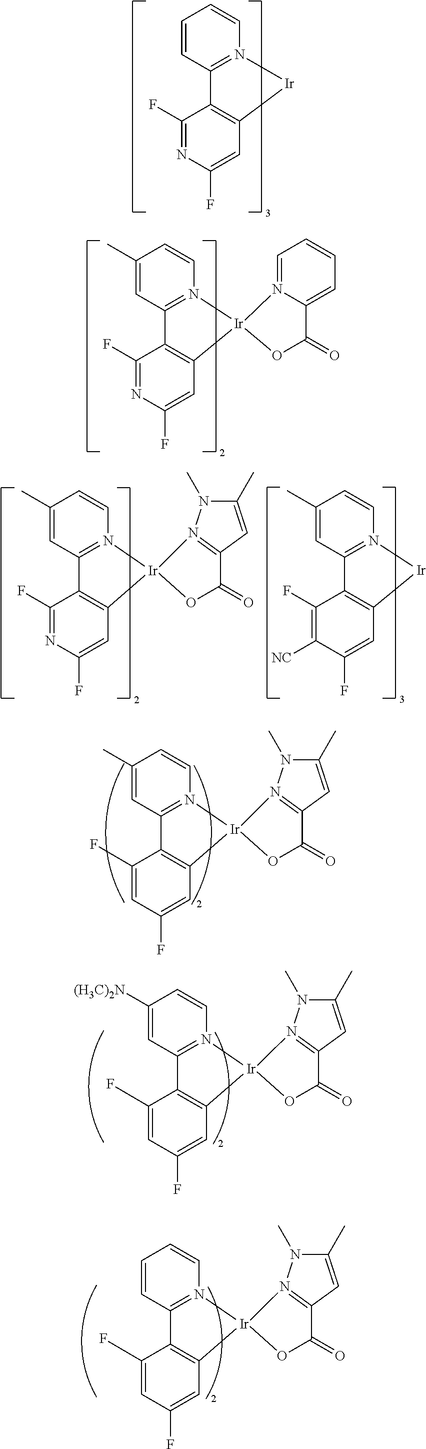

For example, the red phosphorescent metal complex may be selected from the following compounds:

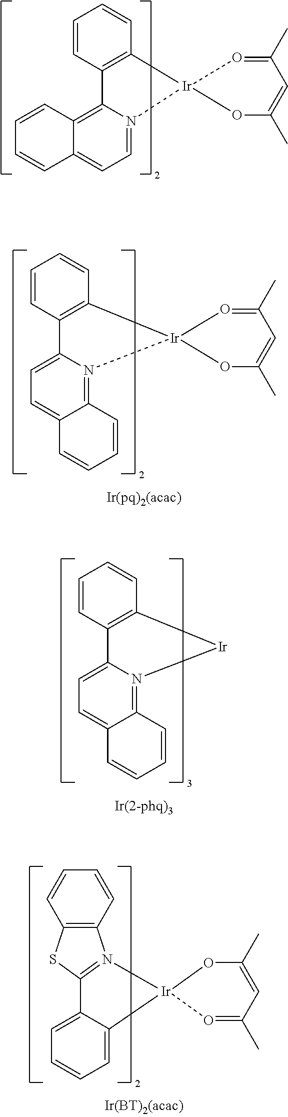

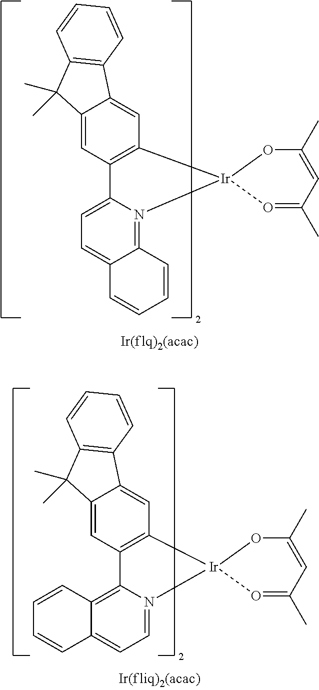

For example, the green phosphorescent metal complex may be selected from the following compounds:

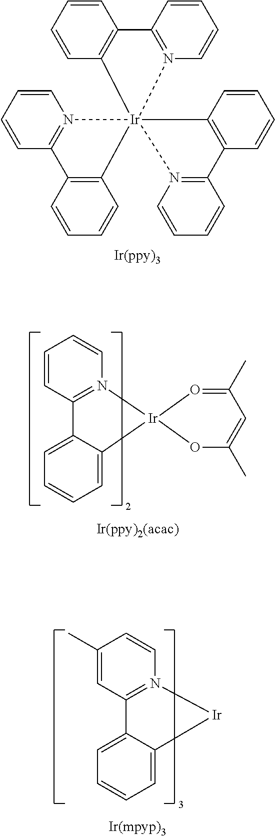

In an implementation, examples of the phosphorescent metal complex included in the dopant of the emission layer may include one of the complexes D1 to D50, below:

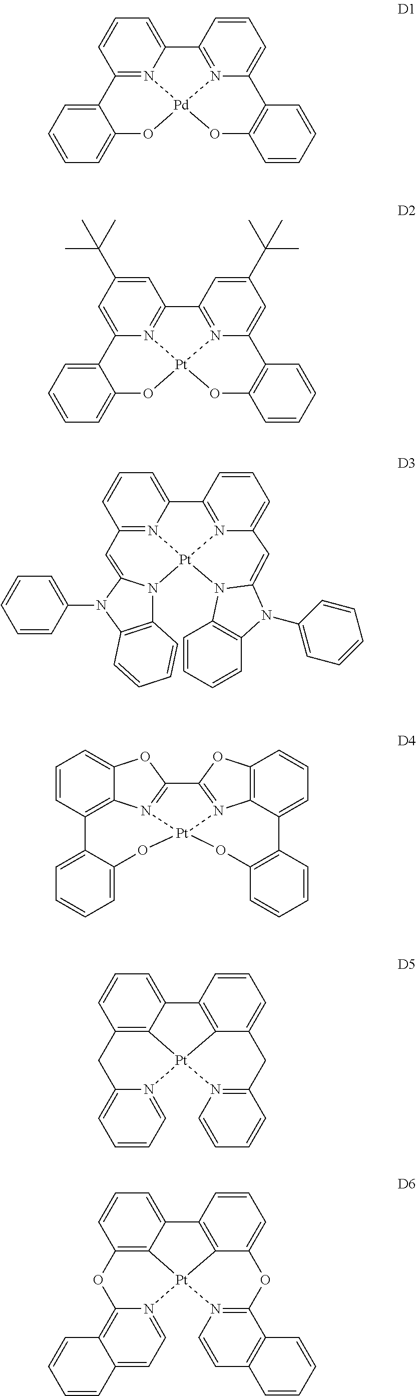

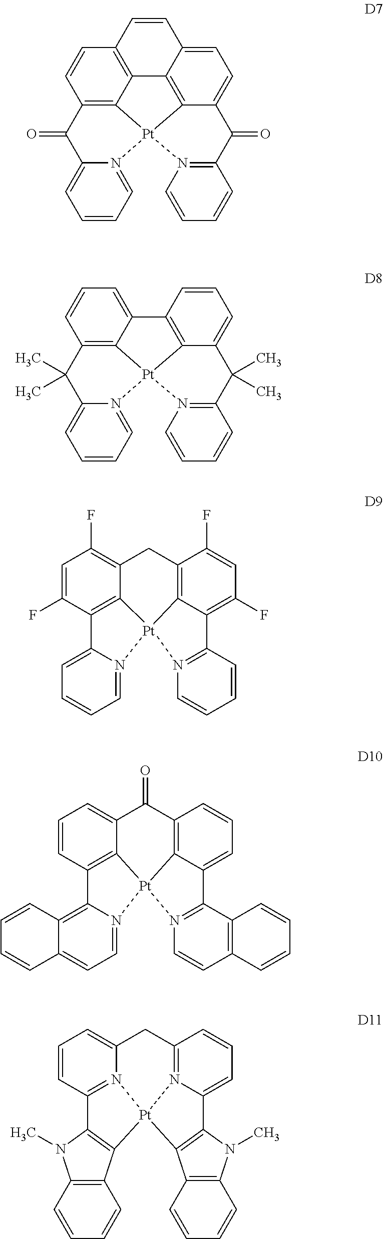

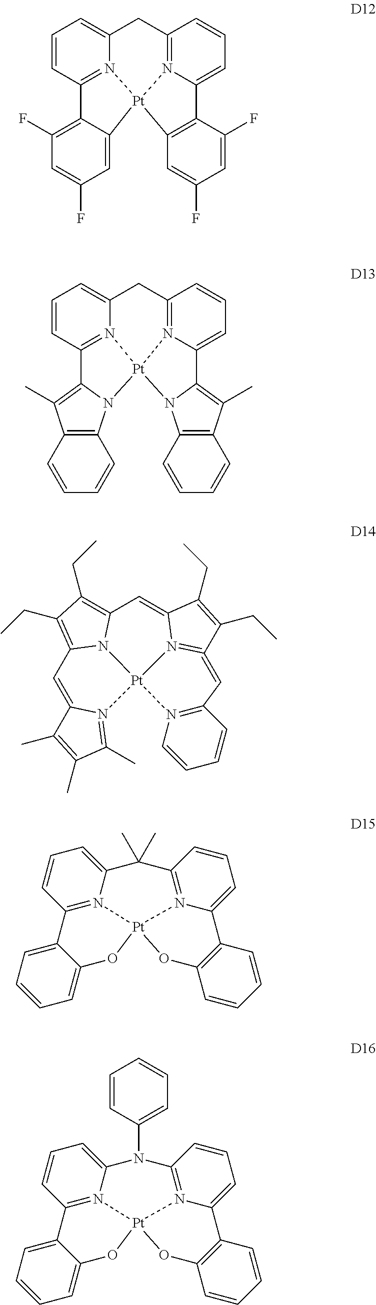

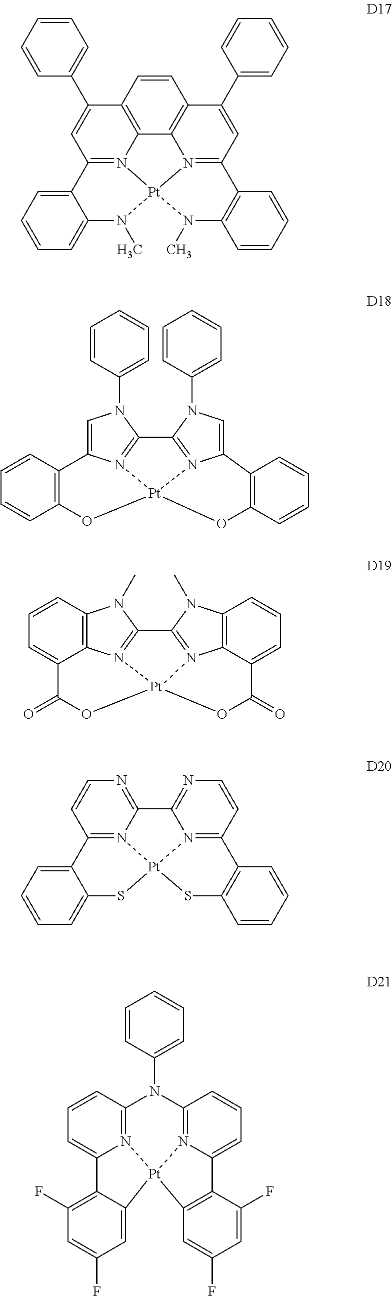

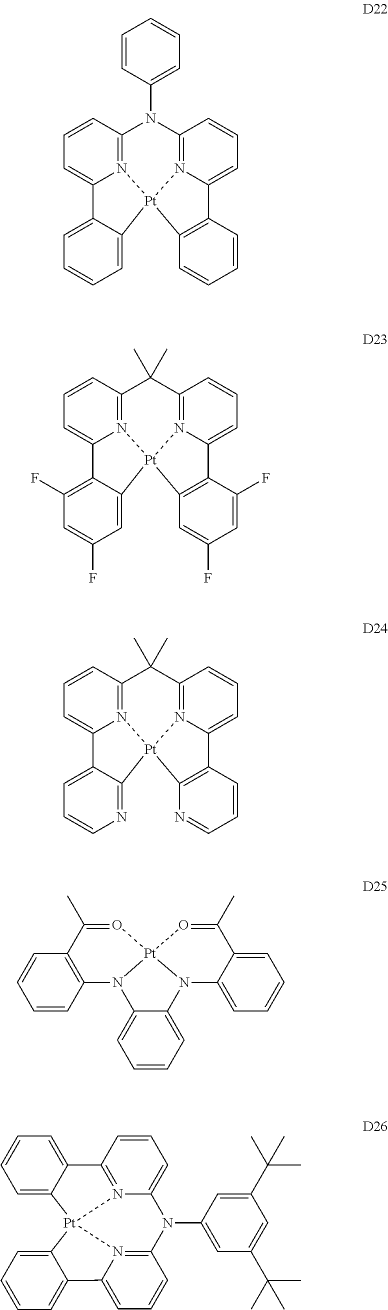

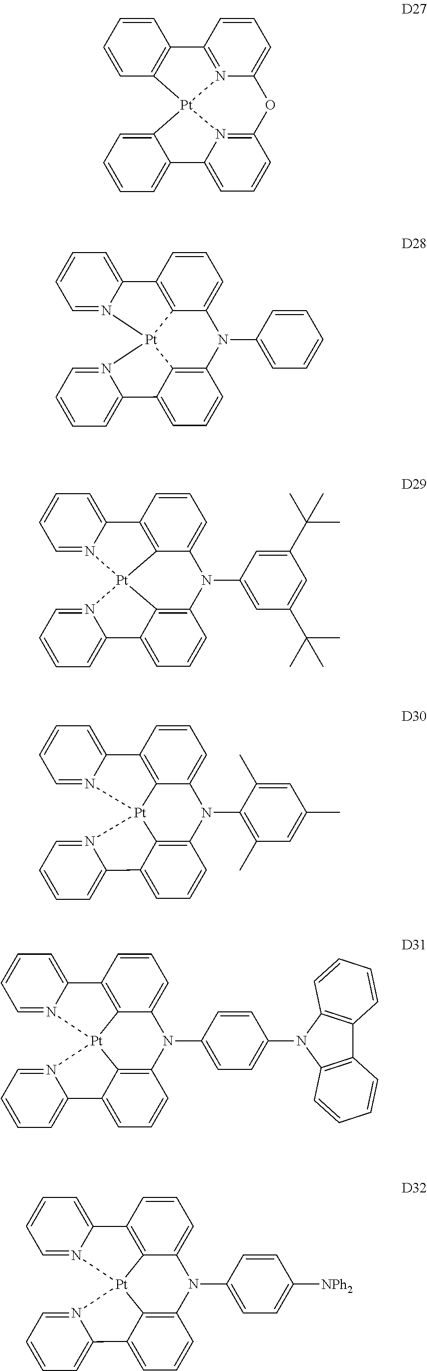

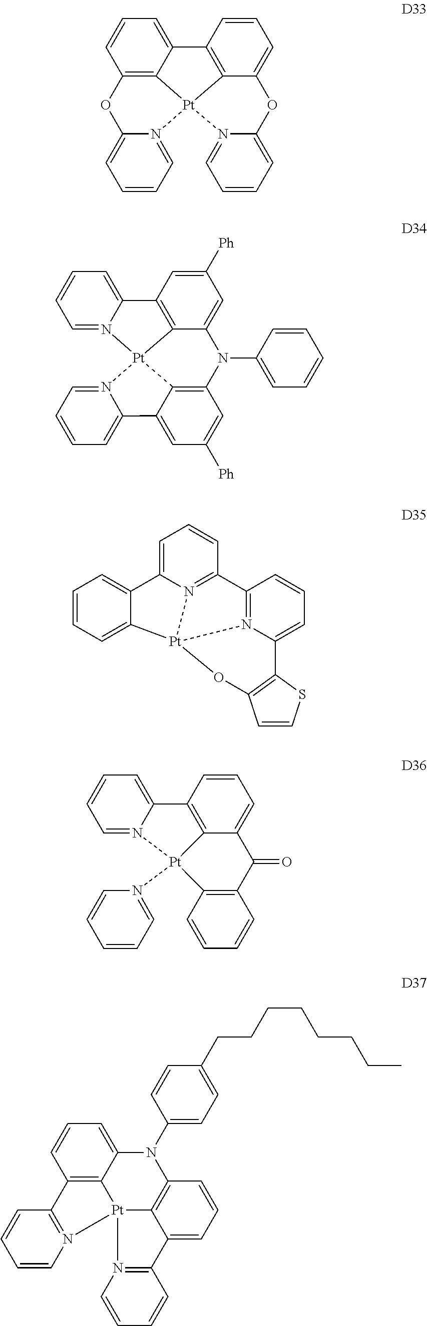

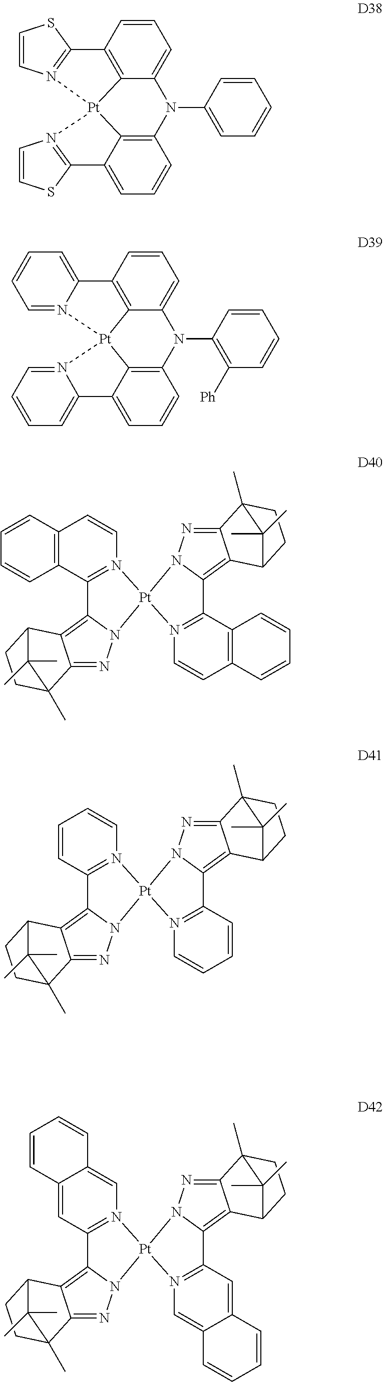

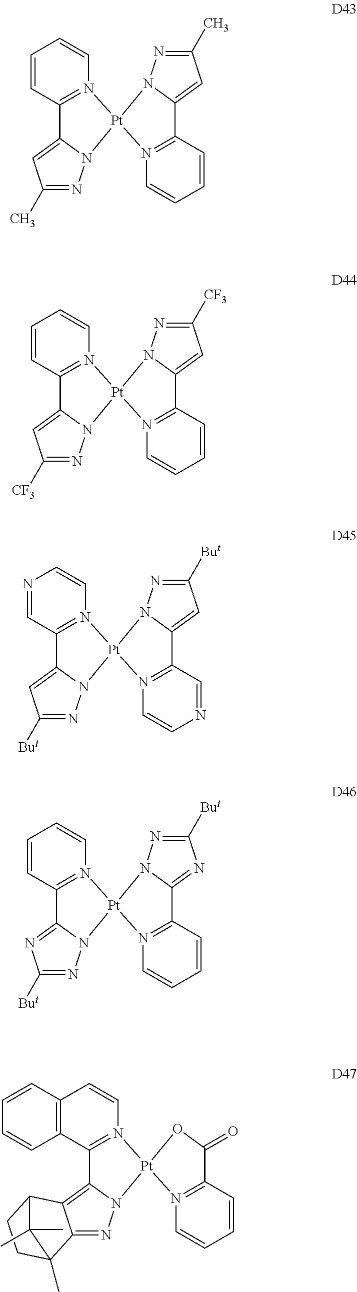

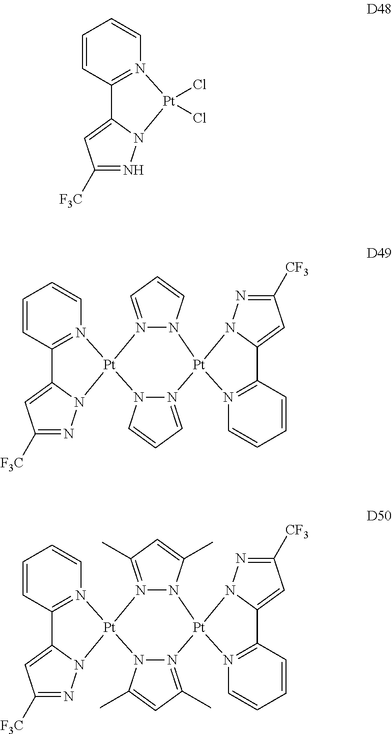

In an implementation, the phosphorescent metal complex included in the dopant of the emission layer may include an Os-complex. For example, the Os-complex may include one of the Os-complexes, below.

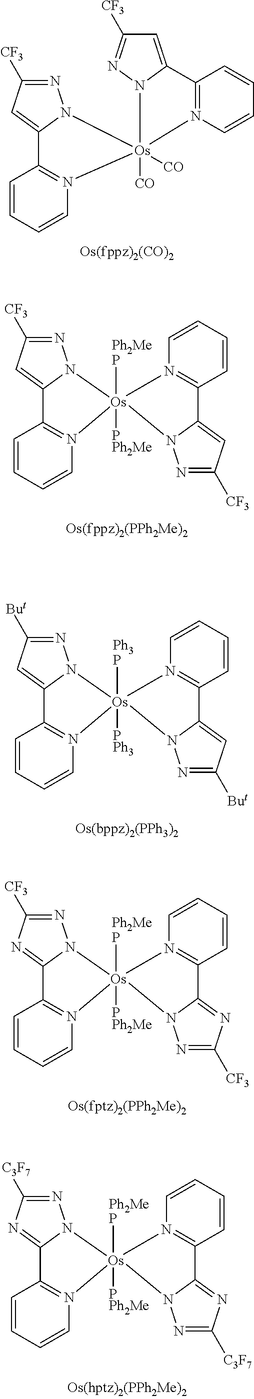

In an implementation, an amount of the dopant in the emission layer may be, e.g., from about 0.01 parts by weight to about 15 parts by weight, based on 100 parts by weight of the host.

According to an embodiment, the first carbazole-based compound (included in the first hole transport layer) may be represented by Formula 1, below, the second carbazole-based compound (included in the second hole transport layer) may be represented by Formula 2, below, and the third carbazole-based compound (included in the host of the emission layer) may be represented by Formula 3, below:

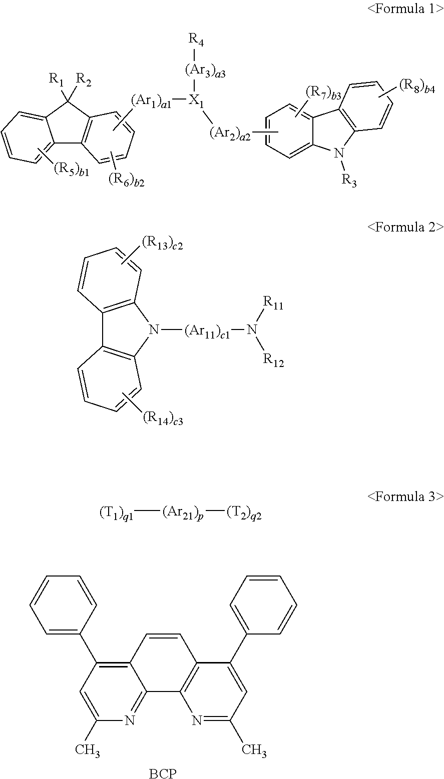

X₁ in Formula 1 may be selected from N, B, and P. For example, X₁ in Formula 1 may be N.

Ar₁ to Ar₃, and Ar₁₁, and Ar₂₁ in Formulae 1 to 3 may be each independently selected from a substituted or unsubstituted C₃-C₁₀ cycloalkylene group, a substituted or unsubstituted heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, or a substituted or unsubstituted C₂-C₆₀ heteroarylene group.

For example, Ar₁ to Ar₃, and Ar₁ₗ and Ar₂₁ in Formulae 1 to 3 may be each independently selected from:

a phenylene group, a pentalenylene group, an indenylene group, a naphthylene group, an azulenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene, a picenylene group, a perylenylene group, a pentaphenylene group, a hexacenylene group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzooxazolylene group, a benzoimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a benzooxazolylene group, a dibenzopuranylene group, a dibenzothiophenylene group, or a benzocarbazolyl group; or

a phenylene group, a pentalenylene group, an indenylene group, a naphthylene group, an azulenylene group, an indacenylene group, an acenaphthylene group, a fluorenylene group, a spiro-fluorenylene group, a phenalenylene group, a phenanthrenylene group, an anthracenylene group, a fluoranthenylene group, a triphenylenylene group, a pyrenylene group, a chrysenylene group, a naphthacenylene, a picenylene group, a perylenylene group, a pentaphenylene group, a hexacenylene group, a pyrrolylene group, an imidazolylene group, a pyrazolylene group, a pyridinylene group, a pyrazinylene group, a pyrimidinylene group, a pyridazinylene group, an isoindolylene group, an indolylene group, an indazolylene group, a purinylene group, a quinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzooxazolylene group, a benzoimidazolylene group, a furanylene group, a benzofuranylene group, a thiophenylene group, a benzothiophenylene group, a thiazolylene group, an isothiazolylene group, a benzothiazolylene group, an isoxazolylene group, an oxazolylene group, a triazolylene group, a tetrazolylene group, an oxadiazolylene group, a triazinylene group, a benzooxazolylene group, a dibenzopuranylene group, a dibenzothiophenylene group, or a benzocarbazolyl group, each substituted with at least one of:

a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;

a C₁-C₂₀ alkyl group or a C₁-C₂₀ alkoxy group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a C₆-C₂₀ aryl group or a C₂-C₂₀ heteroaryl group;

a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₃)(Q₁₄)(Q₁₅) (wherein Q₁₁ to Q₁₅ are each independently a C₁-C₂₀ alkyl group, a C₁-C₂₀ alkoxy group, a C₆-C₂₀ aryl group, or a C₂-C₂₀ heteroaryl group).

For example, Ar₁ to Ar₃, Ar₁₁ and Ar₂₁ in Formulae 1 to 3 may be each independently represented by one of Formulae 10-1 to 10-24 below. In Formulae 10-1 to 10-24, * represents a binding site with other groups of Formulae 1 to 3.

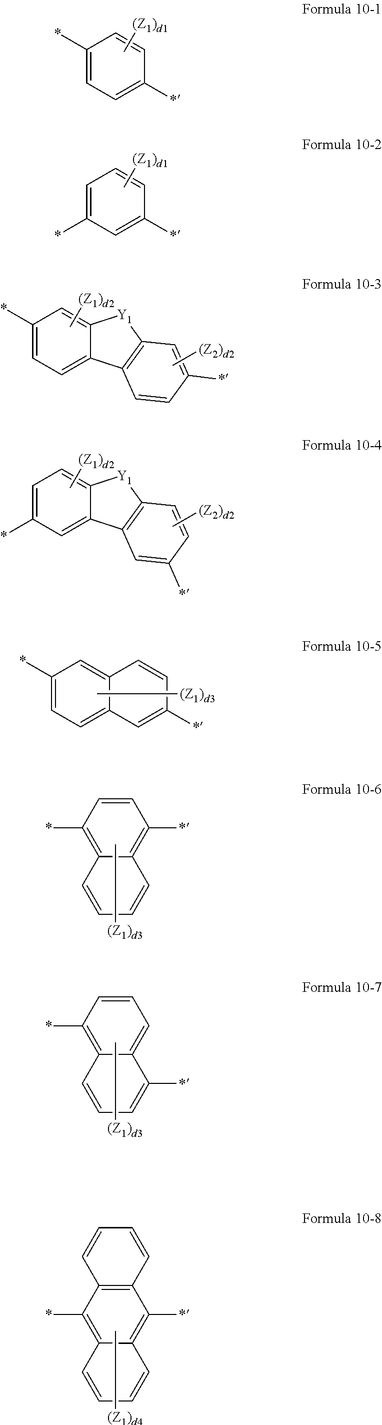

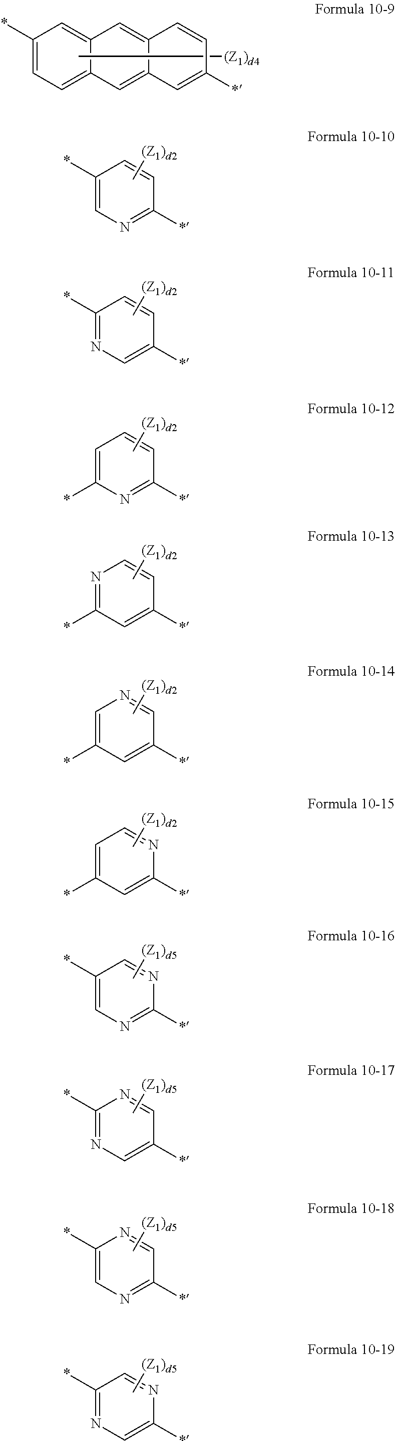

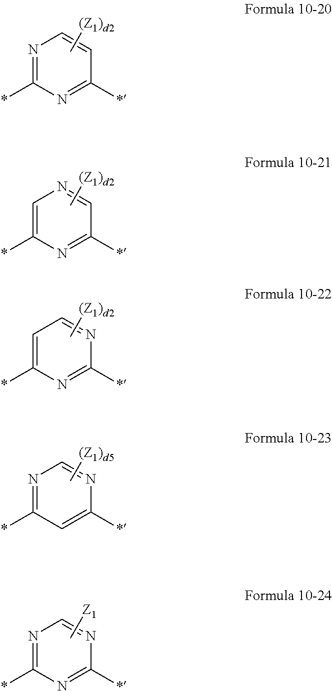

In Formulae 10-1 to 10-24, Y₁ is O, S, C(R₂₁)(R₂₂), or N(R₂₃); and Z₁, Z₂, and R₂₁ to R₂₃ may be each independently selected from:

a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;

a C₁-C₂₀ alkyl group or a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a C₆-C₂₀ aryl group or a C₂-C₂₀ heteroaryl group;

a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₃)(Q₁₄)(Q₁₅) (wherein Q₁₁ to Q₁₅ are each independently a C₁-C₂₀ alkyl group, a C₁-C₂₀ alkoxy group, a C₆-C₂₀ aryl group, or a C₂-C₂₀ heteroaryl group).

d1 may be an integer of 1 to 4; d2 may be an integer of 1 to 3; d3 may be an integer of 1 to 6; d4 may be an integer of 1 to 8; and d5 may be 1 or 2.

For example, Z₁, Z₂, and R₂₁ to R₂₃ may be each independently selected from:

a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;

a C₁-C₂₀ alkyl group or a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group;

a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₃)(Q₁₄)(Q₁₅) (wherein the Q₁₁ to Q₁₅ are each independently C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group).

In Formulae 10-1 to 10-24, d1 may be an integer of 1 to 4; d2 may be an integer of 1 to 3; d3 may be an integer of 1 to 6; d4 may be an integer of 1 to 8; and d5 may be an integer of 1 or 2.

According to an embodiment, Ar₁ to Ar₃, Ar₁₁ and Ar₂₁ in Formulae 1 to 3 may be each independently represented by one of Formulae 11-1 to 11-11, below. In Formulae 11-1 to 11-11, * represents a binding site with other groups of Formulae 1 to 3.

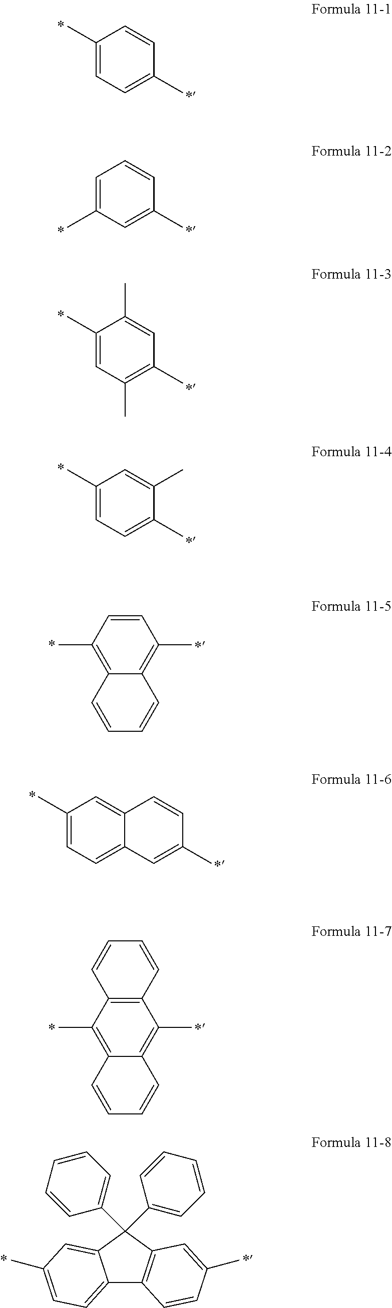

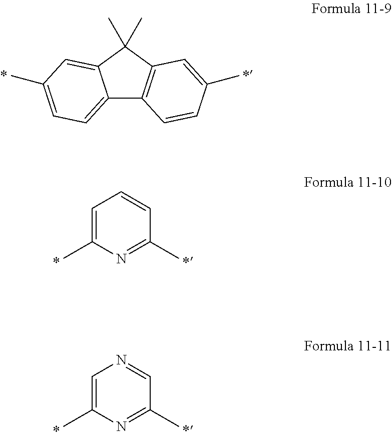

In Formula 1, a1 indicates the number of Ar₁, a2 indicates the number of Ar₂, and a3 indicates the number of Ar₃. a1 to a3 may each independently be an integer of 0 to 5, e.g., an integer of 0 to 3. When a1 and/or a2 is 0, “carbazole” and/or “fluorene” of Formula 1 may be directly linked to “N”. When a1 is 2 or more, a plurality of Ar₁ may be identical to or different from each other. When a2 is 2 or more, a plurality of Ar₂ may be identical to or different from each other. When a3 is 2 or more, a plurality of Ar₂ may be identical to or different from each other.

According to an embodiment, in Formula 1, i) a1 is 0 and a2 is 0; ii) a1 is 1 and a2 is 0; iii) a1 is 2 and a2 is 0; iv) a1 is 0 and a2 is 1; v) a1 is 0 and a2 is 2; or vi) a1 is 1 and a2 is 1.

c1 in Formula 2 indicates the number of Ar₁₁. c1 may be an integer of 1 to 5, e.g., 1, 2, or 3. When c1 is 2 or more, a plurality of Ar₁₁ may be identical to or different from each other.

p in Formula 3 indicates the number of Ar₂₁, and may be an integer from 0 to 5. For example, p may be 0, 1, 2, or 3. When p is 0, T₁ and T₂ in Formula 1 may be directly linked to each other. When p is 2 or more, a plurality of Ar₂₁ may be identical to or different from each other.

In Formulae 1 and 2:

R₁, R₂, R₄ to R₈, R₁₃, and R₁₄ may be each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁)(Q₂), or —Si(Q₃)(Q₄)(Q₅) (wherein Q₁ to Q₅ are each independently a C₁-C₆₀ alkyl group, a C₁-C₆₀ alkoxy group, a C₆-C₆₀ aryl group, or a C₂-C₆₀ heteroaryl group); and

R₃, R₁₁, and R₁₂ may be each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, or —Si(Q₃)(Q₄)(Q₅) (wherein Q₁ to Q₅ are each independently selected from a C₁-C₆₀ alkyl group, a C₁-C₆₀ alkoxy group, a C₆-C₆₀ aryl group, or a C₂-C₆₀ heteroaryl group).

In an implementation, R₁ to R₈ and R₁₁ to R₁₄ in Formulae 1 and 2 may be each independently selected from:

phenyl, pentalenyl, indenyl, naphthyl, azulenyl, heptalenyl, indacenyl, acenaphthyl, fluorenyl, spiro-a fluorenyl, phenalenyl, phenanthrenyl, anthracenyl, fluoranthenyl, triphenylenyl, pyrenyl, chrysenyl, naphthacenyl, picenyl, perylenyl, pentaphenyl, hexacenyl, pyrrolyl, imidazolyl, pyrazolyl, pyridinyl, pyrazinyl, pyrimidinyl, pyridazinyl, isoindolyl, indolyl, indazolyl, purinyl, quinolinyl, benzoquinolinyl, phthalazinyl, naphthyridinyl, quinoxalinyl, quinazolinyl, cinnolinyl, carbazolyl, phenanthridinyl, acridinyl, phenanthrolinyl, phenazinyl, benzooxazolyl, benzoimidazolyl, furanyl, benzofuranyl, thiophenyl, benzothiophenyl, thiazolyl, isothiazolyl, benzothiazolyl, isoxazolyl, oxazolyl, triazolyl, tetrazolyl, oxadiazolyl, triazinyl, benzooxazolyl, dibenzofuranyl, dibenzothiophenyl, or benzocarbazolyl; or

phenyl, pentalenyl, indenyl, naphthyl, azulenyl, heptalenyl, indacenyl, acenaphthyl, fluorenyl, spiro-a fluorenyl, phenalenyl, phenanthrenyl, anthracenyl, fluoranthenyl, triphenylenyl, pyrenyl, chrysenyl, naphthacenyl, picenyl, perylenyl, pentaphenyl, hexacenyl, pyrrolyl, imidazolyl, pyrazolyl, pyridinyl, pyrazinyl, pyrimidinyl, pyridazinyl, isoindolyl, indolyl, indazolyl, purinyl, quinolinyl, benzoquinolinyl, phthalazinyl, naphthyridinyl, quinoxalinyl, quinazolinyl, cinnolinyl, carbazolyl, phenanthridinyl, acridinyl, phenanthrolinyl, phenazinyl, benzooxazolyl, benzoimidazolyl, furanyl, benzofuranyl, thiophenyl, benzothiophenyl, thiazolyl, isothiazolyl, benzothiazolyl, isoxazolyl, oxazolyl, triazolyl, tetrazolyl, oxadiazolyl, triazinyl, benzooxazolyl, dibenzofuranyl, dibenzothiophenyl, or benzocarbazolyl, each substituted with at least one of:

a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;

a C₁-C₂₀ alkyl group or a C₁-C₂₀ alkoxy group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a C₆-C₂₀ aryl group or a C₂-C₂₀ heteroaryl group;

a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₃)(Q₁₄)(Q₁₅) (wherein the Q₁₁ to Q₁₅ are each independently a C₁-C₂₀ alkyl group, a C₁-C₂₀ alkoxy group, a C₆-C₂₀ aryl group, or a C₁-C₂₀ heteroaryl group).

For example, R₃ to R₈ and R₁₁ to R₁₄ in Formulae 1 and 2 may be each independently represented by one of Formulae 12-1 to 12-22, below. In Formulae 12-1 to 12-22, * represents a binding site to other groups in Formulae 1 and 2.

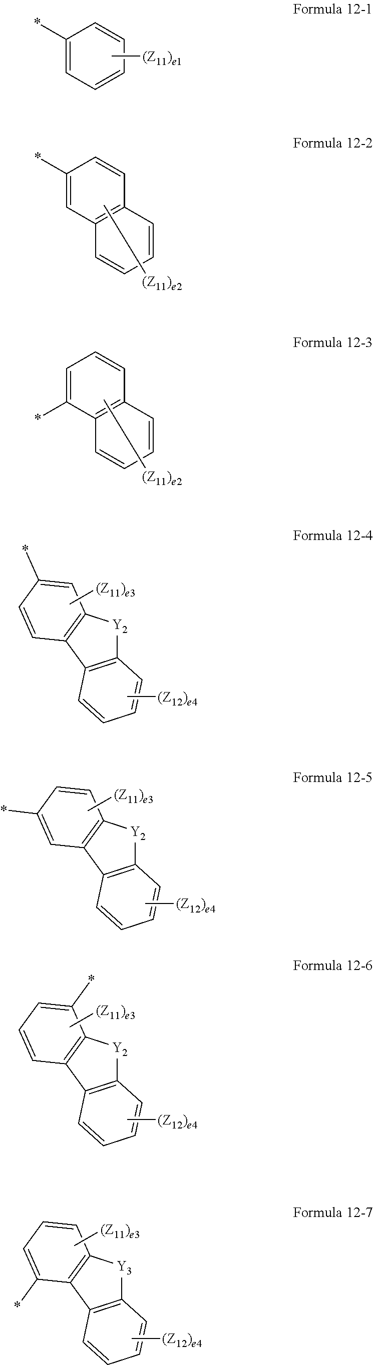

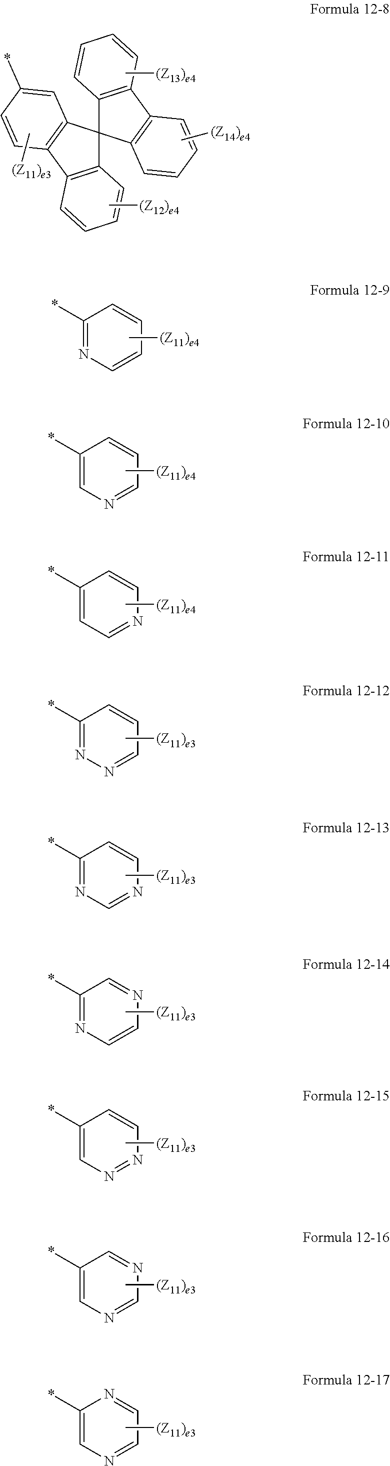

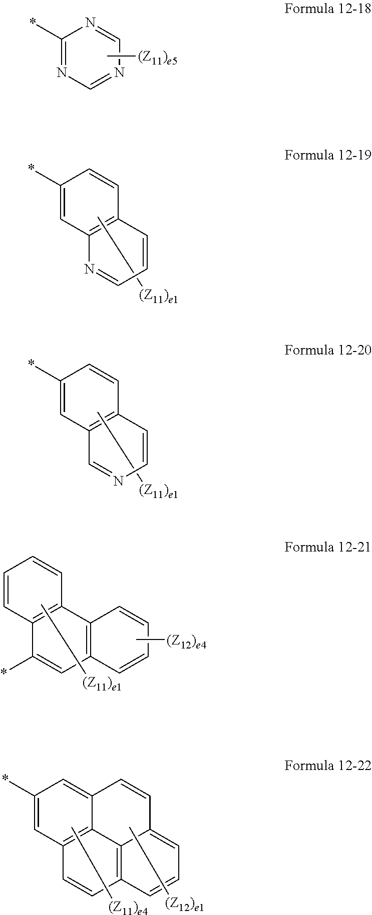

In Formulae 12-1 to 12-22, Y₂ may be O, S, C(R₂₅)(R₂₆), or N(R₂₇); and Z₁₁ to Z₁₄ and R₂₅ to R₂₇ may be each independently selected from:

a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;

a C₁-C₂₀ alkyl group or a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a C₆-C₂₀ aryl group or a C₂-C₂₀ heteroaryl group;

a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₃)(Q₁₄)(Q₁₅) (wherein Q₁₁ to Q₁₅ are each independently selected from a C₁-C₂₀ alkyl group, a C₁-C₂₀ alkoxy group, a C₆-C₂₀ aryl group, or a C₂-C₂₀ heteroaryl group).

e1 may be an integer of 1 to 5; e2 may be an integer of 1 to 7; e3 may be an integer of 1 to 3; e4 may be an integer of 1 to 4; and e5 may be 1 or 2.

According to another embodiment, R₃ to R₈ and R₁₁ to R₁₄ in Formulae 1 and 2 may be each independently represented by one of Formulae 13-1 to 13-19, below. In Formulae 13-1 to 13-19, * represents a binding site with other groups in Formulae 1 and 2.

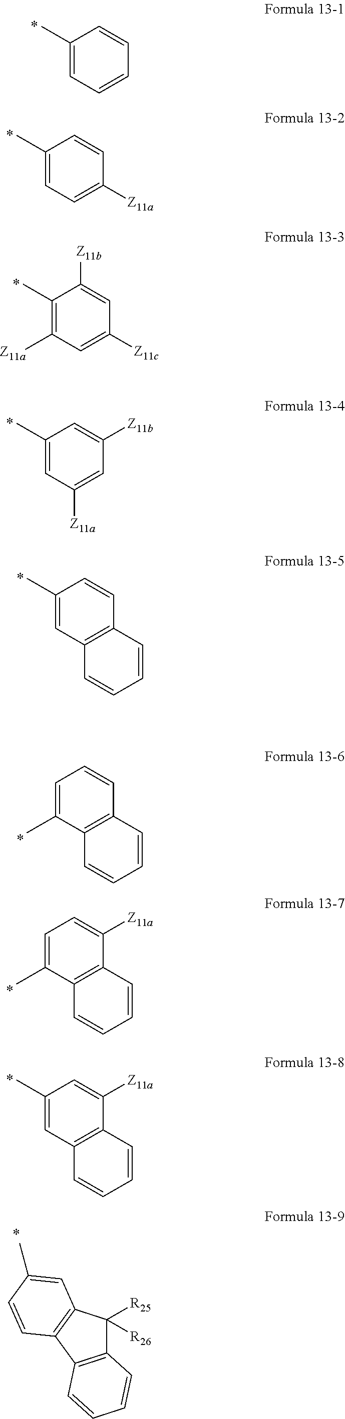

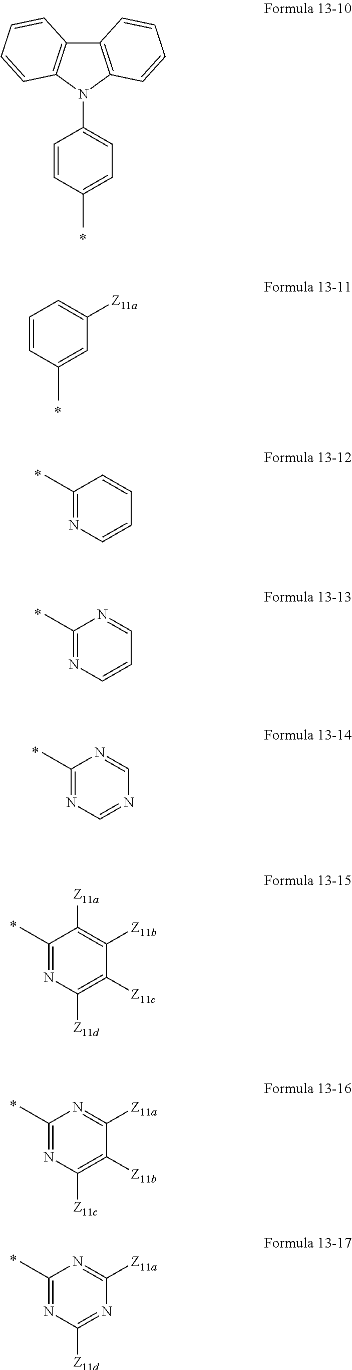

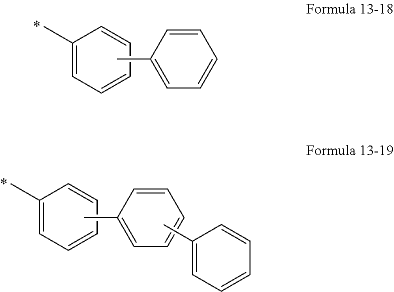

Z₁₁ₐ, to Z_{11c} in Formulae 13-1 to 13-19 may be understood by referring to the description provided in connection with Z₁₁.

For example, Z₁₁ₐ, to Z_{11c}, R₂₅ and R₂₆ in Formulae 13-1 to 13-19 may be each independently selected from:

a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;

a C₁-C₂₀ alkyl group or a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group; or

a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

In an implementation, R₁ and R₂ in Formula 1 may be each independently selected from:

a C₁-C₂₀ alkyl group;

a C₁-C₂₀ alkyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group; or

a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

In Formula 1, b1 indicates the number of R₅, b2 indicates the number of R₆, b3 indicates the number of R₇, and b4 indicates the number of R₈, and in Formula 2, c2 indicates the number of R₁₃ and c3 indicates the number of R₁₄. b1, b4, c2 and c3 may be each independently an integer of 1 to 4, and b2 and b3 may be each independently an integer of 1 to 3.

In an implementation, the first carbazole-based compound included in the first hole transport layer (e.g., represented by Formula 1) may be represented by Formula 1A(1) or 1B(1) below.

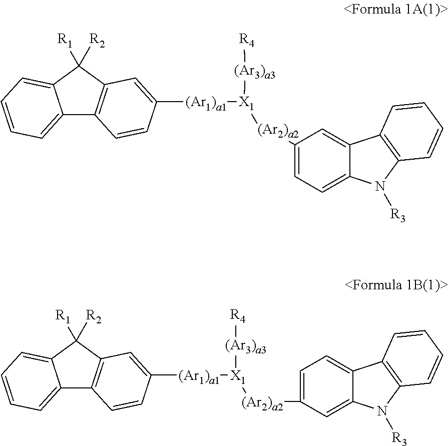

R₁ to R₄, Ar₁ to Ar₃, X₁, a1, a2 and a3 in Formulae 1A(1) and 1B(1) are the same as described above.

T₁ in Formula 3 may be selected from a substituted or unsubstituted a carbazolyl group, a substituted or unsubstituted azacarbazolyl group, or a substituted or unsubstituted condensed carbazolyl group; T₂ may be a N-containing cyclic group; and q1 and q2 may be each independently an integer of 1 to 5.

According to an embodiment, T₁ in Formula 3 may be selected from:

a carbazolyl group, an azacarbazolyl group, a benzocarbazolyl group, a naphthocarbazolyl group, or an indolocarbazolyl group; or

a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁₁)(Q₁₂), or —Si(Q₁₃)(Q₁₄)(Q₁₅) (wherein Q₁₁ to Q₁₅ are each independently a C₁-C₆₀ alkyl group, a C₁-C₆₀ alkoxy group, a C₆-C₆₀ aryl group, or a C₂-C₆₀ heteroaryl group).

T₂ in Formula 3 may be selected from:

an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group; or

an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁₁)(Q₁₂), or—Si(Q₁₃)(Q₁₄)(Q₁₅) (wherein Q₁₁ to Q₁₅ are each independently a C₁-C₆₀ alkyl group, a C₁-C₆₀ alkoxy group, a C₆-C₆₀ aryl group, or a C₂-C₆₀ heteroaryl group).

In an implementation, T₁ in Formula 3 may be selected from:

a carbazolyl group, an azacarbazolyl group, a benzocarbazolyl group, a naphthocarbazolyl group, or an indolocarbazolyl group; or

a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

In an implementation, T₂ in Formula 3 may be selected from:

an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group; or

an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

In Formula 3, q1 indicates the number of T₁, and q2 indicates the number of T₂. q1 and q2 may be each independently an integer of 1 to 5. For example, q1 and q2 may be each independently 1 or 2.

In an implementation, the first carbazole-based compound included in the first hole transport layer may include, e.g., at least one compound selected from N-([1,1′-biphenyl]-4-yl)-9,9-dimethyl-N-(4-(9-phenyl-9H-carbazol-3-yl)phenyl)-9H-fluoren-2-amine, N-([1,1′-biphenyl]-4-yl)-9,9-diphenyl-N-(4-(9-phenyl-9H-carbazol-3-yl)phenyl)-9H-fluoren-2-amine, or N,9,9-triphenyl-N-(4-(9-phenyl-9H-carbazol-3-yl)phenyl)-9H-fluoren-2-amine.

In an implementation, the second carbazole-based compound included in the second hole transport layer may include, e.g., at least one compound selected from 4-(9H-carbazol-9-yl)-N,N-diphenylaniline, 3,5-di(9H-carbazol-9-yl)-N,N-diphenylaniline, 6-(9H-carbazol-9-yl)-N,N-diphenylnaphthalen-2-amine, 4′-(9H-carbazol-9-yl)-N,N-diphenyl-[1,1′-biphenyl]-4-amine, N-(4′-(9H-carbazol-9-yl)-[1,1′-biphenyl]-4-yl)-N-phenylnaphthalen-1-amine, or N,N-di([1,1′-biphenyl]-4-yl)-7-(9H-carbazol-9-yl)-9,9-dimethyl-9H-fluoren-2-amine.

In an implementation, the third carbazole-based compound included in the emission layer may include, e.g., 4,4′-N,N′-dicarbazole-biphenyl, N,N′-dicarbazolyl-3,5-benzene, 2,6-bis(3-(9H-carbazol-9-yl)phenyl)pyridine, 2,6-bis(3-(9H-carbazol-9-yl)phenyl)pyrazine, 9-(4,6-diphenylpyrimidin-2-yl)-3,6-diphenyl-9H-carbazole, 9-(4,6-diphenyl-1,3,5-triazin-2-yl)-9H-carbazole, 9-phenyl-9′-(pyridin-2-yl)-9H,9′H-3,3′-bicarbazole, 9-phenyl-9′-(quinolin-2-yl)-9H,9′H-3,3′-bicarbazole, 9-([1,1′-biphenyl]-3-yl)-9′-(pyridin-2-yl)-9H,9′H-3,3′-bicarbazole, 9-(4,6-diphenyl-1,3,5-triazin-2-yl)-9′-phenyl-9H,9′H-3,3′-bicarbazole, 9-(4,6-diphenylpyrimidin-2-yl)-9′-phenyl-9H,9′H-3,3′-bicarbazole, or 5-phenyl-11-(pyridin-2-yl)-5,11-dihydroindolo[3,2-b]carbazole.

At least one substituent of the substituted C₃-C₁₀ cycloalkylene group, the substituted C₂-C₁₀ heterocycloalkylene group, the substituted C₃-C₁₀ cycloalkenylene group, the substituted C₂-C₁₀ heterocycloalkenylene group, the substituted C₆-C₆₀ arylene group, the substituted C₂-C₆₀ heteroarylene group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₂-C₆₀ heteroaryl group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₆-C₆₀ aryloxy group, or the substituted C₆-C₆₀ arylthyo group may be selected from:

a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthyo group, or a C₂-C₆₀ heteroaryl group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthyo group, or a C₂-C₆₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₃)(Q₁₄)(Q₁₅) (wherein Q₁₁ to Q₁₅ are each independently selected from a C₁-C₆₀ alkyl group, a C₁-C₆₀ alkoxy group, a C₆-C₆₀ aryl group, or a C₂-C₆₀ heteroaryl group).

The unsubstituted C₁-C₆₀ alkyl group (or a C₁-C₆₀ alkyl group) used herein may be a C₁-C₆₀ linear or branched alkyl group, such as methyl group, ethyl group, propyl group, isobutyl group, sec-butyl group, pentyl group, iso-amyl group, or hexyl group.

A substituent of a substituted C₁-C₆₀ alkyl group may be selected from: a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, and a phosphoric acid or a salt thereof; a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₂-C₆₀ heteroaryl group;

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆₀ aryloxy group, a C₆-C₆₀ arylthio group, or a C₂-C₆₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenylfluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or

—N(Q₁₁)(Q₁₂) or —Si(Q₁₁)(Q₁₂)(Q₁₃) (wherein Q₁₁ and Q₁₂ are each independently a C₆-C₆₀ aryl group, or a C₂-C₆₀ heteroaryl group, and Q₁₃ to Q₁₅ are each independently a C₁-C₆₀ alkyl group, a C₁-C₆₀ alkoxy group, a C₆-C₆₀ aryl group, or a C₂-C₆₀ heteroaryl group).

The unsubstituted C₁-C₆₀ alkoxy group (or a C₁-C₆₀ alkoxy group) used herein may refer to a group represented by —OA (wherein A is the unsubstituted C₁-C₆₀ alkyl group described above). Examples thereof may include methoxy, ethoxy, and isopropyloxy, and one or more hydrogen atoms of these alkoxy groups may be substituted with the same substituents as described in connection with the substituted C₁-C₆₀ alkyl group.

The unsubstituted C₂-C₆₀ alkenyl group (or a C₂-C₆₀ alkenyl group) used herein may refer to an unsubstituted C₂-C₆₀ alkyl group having one or more carbon double bonds at a center or end thereof. Examples of the unsubstituted C₂-C₆₀ alkenyl group may include ethenyl group, prophenyl group, and butenyl. One or more hydrogen atoms of these unsubstituted C₂-C₆₀ alkenyl groups may be substituted with the same substituents as described in connection with the substituted C₁-C₆₀ alkyl group.

The unsubstituted C₂-C₆₀ alkynyl group (or a C₂-C₆₀ alkynyl group) used herein may refer to an unsubstituted C₂-C₆₀ alkyl group having one or more carbon triple bonds at a center or end thereof. Examples of the unsubstituted C₂-C₆₀ alkynyl group may include ethynyl group, propynyl group, and the like. One or more hydrogen atoms of these alkynyl groups may be substituted with the same substituents as described in connection with the substituted C₁-C₆₀ alkyl group.

The unsubstituted C₆-C₆₀ aryl group used herein may be a monovalent group having a carbocyclic aromatic system having 6 to 60 carbon atoms including at least one aromatic ring. The unsubstituted C₆-C₆₀ arylene group may be a divalent group having a carbocyclic aromatic system having 6 to 60 carbon atoms including at least one aromatic ring. When the aryl group and or the arylene group have at least two rings, they may be fused to each other, e.g., via a single bond. One or more hydrogen atoms of the aryl group and the arylene group may be substituted with the same substituents as described in connection with the substituted C₁-C₆₀ alkyl group.

Examples of the substituted or unsubstituted C₆-C₆₀ aryl group may include a phenyl group, a C₁-C₁₀ alkylphenyl group (for example, ethylphenyl group), a C₁-C₁₀ alkylbiphenyl group (for example, ethylbiphenyl group), a halophenyl group (for example, o-, m- and p-fluorophenyl groups, a dichlorophenyl group), a dicyanophenyl group, a trifluoromethoxyphenyl group, o-, m-, and p-tolyl groups, o-, m- and p-cumenyl groups, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, a fluoronaphthyl group), a C₁-C₁₀ alkylnaphthyl group (for example, methyla naphthyl group), a C₁-C₁₀ alkoxynaphthyl group (for example, a methoxynaphthyl group), an anthracenyl group, an azrenyl group, a heptalenyl group, an acenaphthylenyl group, a phenalenyl group, a fluorenyl group, an anthraquinolinyl group, ananthracenyl group, a phenanthrenyl group, a triphenylenyl group, a pyrenyl group, a chrysenyl group, an ethyl-chrysenyl group, a picenyl group, a perylenyl group, a chloroperylenyl group, a pentaphenyl group, a pentasenyl group, a tetraphenylenyl group, a hexaphenyl group, a hexacenyl group, a rubicenyl group, a coroneryl group, a trinaphthylenyl group, a heptaphenyl group, a heptacenyl group, a piranthrenyl group, and an obarenyl group. Examples of the substituted C₆-C₆₀ aryl group may be easily understood by referring to the examples of the unsubstituted C₆-C₆₀ aryl group, and the substituents of the substituted C₁-C₆₀ alkyl group. Examples of the substituted or unsubstituted C₆-C₆₀ arylene group may be easily understood by referring to examples of the substituted or unsubstituted C₆-C₆₀ aryl group.

The unsubstituted C₂-C₆₀ heteroaryl group used herein may refer to a monovalent group having a system composed of one or more aromatic rings having at least one hetero atom selected from nitrogen (N), oxygen (O), phosphorous (P), and sulfur (S) and carbon atoms as the remaining ring atoms. The unsubstituted C₂-C₆₀ heteroarylene group used herein may refer to a divalent group having a system composed of one or more aromatic rings having at least one hetero atom selected from nitrogen (N), oxygen (O), phosphorous (P), and sulfur (S) and carbon atoms as the remaining ring atoms. When the heteroaryl group and the heteroarylene group have at least two rings, they may be fused to each other, e.g., via a single bond. One or more hydrogen atoms of the heteroaryl group and the heteroarylene group may be substituted with the same substituents as described in connection with the substituted C₁-C₆₀ alkyl group.

Examples of the unsubstituted C₂-C₆₀ heteroaryl group may include a pyrazolyl group, an imidazolyl group, a oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, an imidazolyl group, an imidazo pyridinyl group, and an imidazo pyrimidinyl group. Examples of the substituted or unsubstituted C₂-C₆₀ heteroarylene group may be easily understood by referring to examples of the substituted or unsubstituted C₂-C₆₀ arylene group.

The substituted or unsubstituted C₆-C₆₀ aryloxy group may be represented by —OA₂ (wherein A₂ indicates the substituted or unsubstituted C₆-C₆₀ aryl group), and the substituted or unsubstituted C₆-C₆₀ arylthio group may be represented by —SA₃ (wherein A₃ indicates a substituted or unsubstituted C₆-C₆₀ aryl group).

A total thickness of the first hole transport layer and the second hole transport layer may be in a range of about 50 Å to about 2,500 Å, e.g., about 100 Å to about 2,000 Å. A thickness ratio of the first hole transport layer to the second hole transport layer may be in a range of about 1:9 to about 9:1, e.g., about 3:7 to about 7:3, but is not limited thereto. A thickness of the second hole transport layer may be in a range of about 5 nm to about 300 nm. When the total thickness and the thickness ratio of the first hole transport layer and the second hole transport layer are within these ranges, the first hole transport layer and the second hole transport layer may have a satisfactory hole transporting ability without a substantial increase in driving voltage.

A thickness of the emission layer may be in a range of about 100 Å to about 1,000 Å, e.g., about 200 Å to about 600 Å. When the thickness of the emission layer is within these ranges, the emission layer may have improved luminescent properties without a substantial increase in driving voltage.

The first hole transport layer, the second hole transport layer, and the emission layer may be formed by using suitable methods, such as a deposition method, a spin coating method, or a casting method. When the first hole transport layer, the second hole transport layer, and the emission layer are formed by vacuum deposition or spin coating, the deposition and coating conditions may be similar to those for the formation of the hole injection layer, though the conditions for deposition and coating may vary according to the material that is used to form the first hole transport layer, the second hole transport layer, and the emission layer.

Next, an electron transport layer may be formed on the emission layer using suitable methods, e.g., by vacuum deposition, spin coating, casting, or the like. When the electron transport layer is formed using vacuum deposition or spin coating, the deposition and coating conditions may be similar to those for the formation of the hole injection layer, though the conditions for deposition and coating may vary according to the material that is used to form the electron transport layer.

A material for an electron transport layer may be any one of suitable electron transporting materials that stably transport electrons injected from a second electrode. Examples of the material for the electron transport layer may include a quinoline derivative, such as tris(8-quinolinolate)aluminium (Alq₃), TAZ, Balq, beryllium bis(benzoquinolin-10-olate) (Bebq₂), Compound 201, Compound 202, PBD (2-(4-biphenyl)-5-(4-t-butylphenyl)-1,3,4-oxadiazole) spiro-PBD (spiro-2-biphenyl-4-yl-5-(4-t-butylphenyl)-1,3,4-oxadiazole), and SAlq.

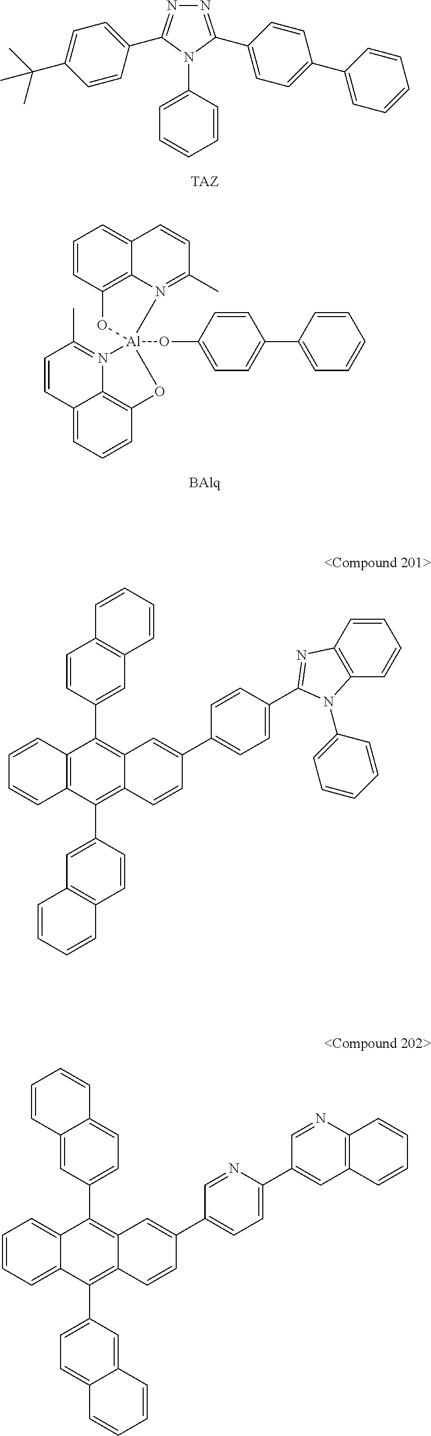

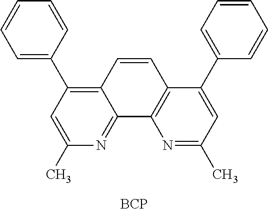 [SMILES: Cc1cc(-c2ccccc2)c2ccc3c(-c4ccccc4)cc(C)nc3c2n1 ; "BCP"]

A thickness of the electron transport layer may be in a range of about 100 Å to about 1,000 Å, e.g., about 150 Å to about 500 Å. When the thickness of the electron transport layer is within these ranges, the electron transport layer may have satisfactory electron transporting ability without a substantial increase in driving voltage.

The electron transport layer may further include, in addition to the electron-transporting organic material, a metal-containing material.

The metal-containing material may include a lithium (Li) complex. Examples of the Li complex may include lithium quinolate (LiQ) and Compound 203, below:

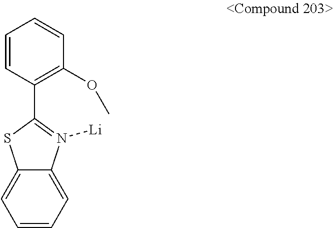

Also, a material for forming an electron injection layer that allows electrons to be easily injected from the second electrode may be deposited on the electron transport layer.

Examples of materials for forming the electron injection layer may include LiF, NaCl, CsF, Li₂O, and BaO. The deposition conditions of the electron injection layer may be similar to those used to form the hole injection layer, although the deposition conditions may vary according to the material that is used to form the electron injection layer.

The thickness of the electron injection layer may be from about 1 Å to about 100 Å, e.g., about 3 Å to about 90 Å. When the thickness of the electron injection layer is within these ranges, the electron injection layer may have satisfactory electron injection ability without a substantial increase in driving voltage.

The following Examples are provided in order to highlight characteristics of one or more embodiments, but it will be understood that the Examples are not to be construed as limiting the scope of the embodiments. Further, it will be understood that the embodiments are not limited to the particular details described in the Examples.

OLED 1 to OLED 6 were manufactured to evaluate efficiency, driving voltage, and lifespan characteristics of an organic light-emitting diode. OLED 6 was manufactured by using the following method.

An ITO glass substrate was cut to a size of 50 mm×50 mm×0.5 mm and then, sonicated in acetone, isopropyl alcohol, and pure water each for 15 minutes, and washed with UV ozone for 30 minutes. HT1 and 2 wt % F4-TCNQ were vacuum deposited on the ITO electrode to form a first hole transport layer having a thickness of 600 Å, and HT2 was vacuum deposited on the first hole transport layer at a deposition speed of 1 Å/sec to form a second hole transport layer having a thickness of 600 Å. Subsequently, PH1 (host) and PRD1 (dopant) were respectively co-deposited on the second hole transport layer at a deposition speed of 1 Å/sec and 0.1 Å/sec to form an emission layer having a thickness of 400 Å. Alq₃ was vacuum deposited on the emission layer to form an electron transport layer having a thickness of 300 Å, and LiF and Al were sequentially vacuum deposited on the electron transport layer to form an electron injection layer having a thickness of 10 Å and a second electrode having a thickness of 2,000 Å, respectively.

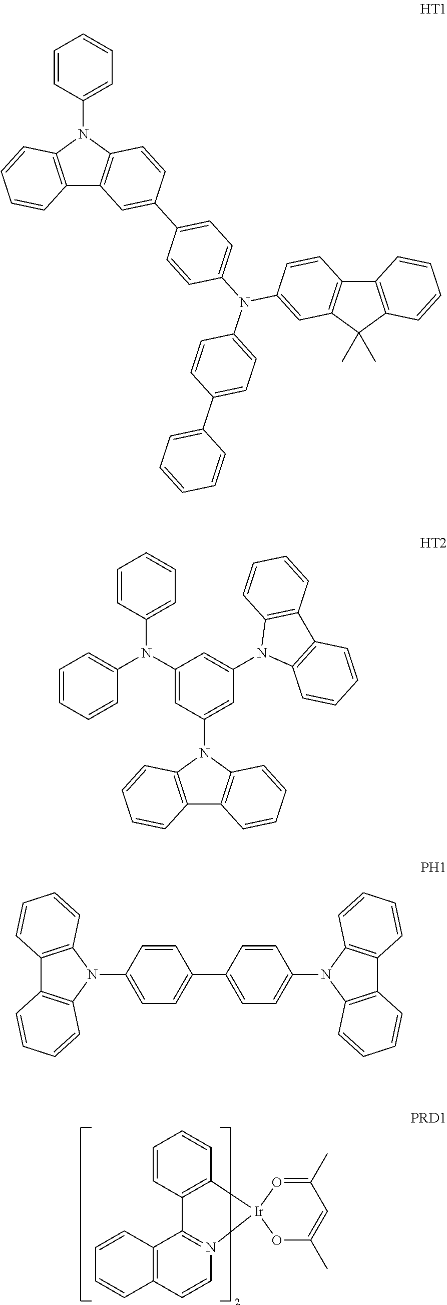

OLED 1 to OLED 5 were manufactured in the same manner as used to manufacture OLED 6, except that materials for and the thicknesses of the first hole transport layer, the second hole transport layer, and the emission layer material were varied as shown in Table 1, below. In the case of OLED 1, an emission layer was formed directly on the first hole transport layer without the formation of the second hole transport layer.

TABLE 1

| | | Second hole | |
|---|---|---|---|
| | | transport | |
| | First hole transport layer | layer | Emission layer |
| OLED 1 | HT1:F4-TCNQ(2wt %) | — | PH1:PRD1(5wt %) |
| | (600 Å) | | (400 Å) |
| OLED 2 | HT1:F4-TCNQ(2wt %) | α-NPB | PH1:PRD1(5wt %) |
| | (600 Å) | (600 Å) | (400 Å) |
| OLED 3 | HT1:F4-TCNQ(2wt %) | HT2 | PH2:PRD1(5wt %) |
| | (600 Å) | (600 Å) | (400 Å) |
| OLED 4 | α-NPB:F4-TCNQ(2wt %) | HT2 | PH1:PRD1(5wt %) |
| | (600 Å) | (600 Å) | (400 Å) |
| OLED 5 | α-NPB:F4-TCNQ(2wt %) | HT2′ | PH2:PRD1(5wt %) |
| | (600 Å) | (600 Å) | (400 Å) |
| OLED 6 | HT1:F4-TCNQ(2wt %) | HT2 | PH1:PRD1(5wt %) |
| | (600 Å) | (600 Å) | (400 Å) |

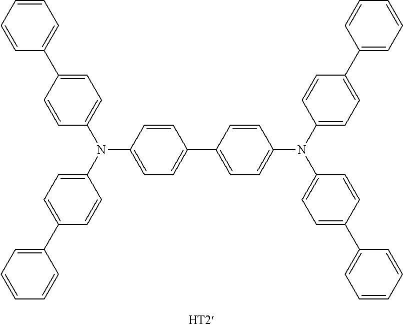 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

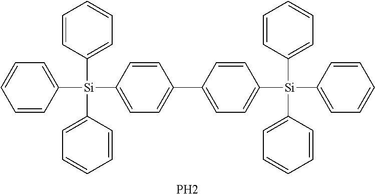

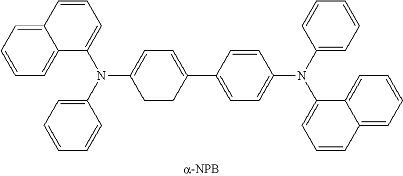 [SMILES: c1ccc(N(c2ccc(-c3ccc(N(c4ccccc4)c4cccc5ccccc45)cc3)cc2)c2cccc3ccccc23)cc1]

Table 2, below, shows efficiency, driving voltage, and T₈₀ lifespan data of OLED 1 to OLED 6. The efficiency, driving voltage, and half lifespan were relatively evaluated as a percentage point with respect to the efficiency, driving voltage and lifespan (100%) of OLED 1. T₈₀ lifespan indicates a time duration (hr) taken to obtain up to 80% brightness of initial brightness in a condition of 150 nit. The efficiency, driving voltage, and brightness were measured by using a luminance meter PR650 while power was supplied by using a current-voltage meter (Kethley SMU 236).

TABLE 2

| | Efficiency | Driving voltage | T₈₀ lifespan |
|---|---|---|---|
| | (cd/A) | (V) | (hr) |
| OLED 1 | 100% | 100% | 100% |
| OLED 2 | 105% | 97% | 91% |
| OLED 3 | 115% | 93% | 111% |
| OLED 4 | 121% | 85% | 145% |
| OLED 5 | 107% | 105% | 70% |
| OLED 6 | 148% | 81% | 192% |

Referring to Table 2, it may be seen that OLED 6 had the highest efficiency and lifespan and the lowest driving voltage.

Organic light-emitting diodes have explained in connection with FIGS. 1 and 2. However, an organic light-emitting diode according to an embodiment is not limited thereto, and may also be embodied in different forms.

An organic light-emitting diode according to an embodiment may include organic layers with improved inter-facial stability, may have prolonged lifespan obtained by controlling an emission area, and may have low-driving voltage, high brightness, and high efficiency. Due to the inclusion of the organic light-emitting diode, a high-quality display apparatus may be embodied.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting diode, comprising:
a first electrode;
a second electrode facing the first electrode;
an emission layer between the first electrode and the second electrode, the emission layer including a host and a dopant;
a first hole transport layer between the first electrode and the emission layer; and
a second hole transport layer between the first hole transport layer and the emission layer,
wherein:
the first hole transport layer includes a first carbazole-based compound and a p-dopant,
the second hole transport layer includes a second carbazole-based compound and does not include the p-dopant,
the host of the emission layer includes a third carbazole-based compound,
the dopant of the emission layer includes a phosphorescent metal complex, and
the first carbazole-based compound, the second carbazole-based compound, and the third carbazole-based compound are all different from each other.

2. The organic light-emitting diode as claimed in claim 1, wherein:
the first hole transport layer directly contacts the second hole transport layer, and
the second hole transport layer directly contacts the emission layer.

3. The organic light-emitting diode as claimed in claim 1, wherein a weight ratio of the p-dopant to the first carbazole-based compound is about 0.1:99.9 to about 20:80.

4. The organic light-emitting diode as claimed in claim 1, wherein a hole mobility of the first carbazole-based compound is greater than a hole mobility of the second carbazole-based compound.

5. The organic light-emitting diode as claimed in claim 1, wherein a difference between a HOMO level of the first hole transport layer and a HOMO level of the second hole transport layer is less than about 0.3 eV.

6. The organic light-emitting diode as claimed in claim 1, wherein a triplet energy of the second carbazole-based compound of the second hole transport layer is greater than a triplet energy of the phosphorescent metal complex of the emission layer.

7. The organic light-emitting diode as claimed in claim 1, wherein a molecular weight of the third carbazole-based compound of the emission layer is about 400 g/mol or higher.

8. The organic light-emitting diode as claimed in claim 1, wherein the phosphorescent metal complex of the emission layer has a maximum phosphorescent emission peak wavelength of about 480 nm to about 650 nm.

9. The organic light-emitting diode of claim 1, wherein the first carbazole-based compound is represented by Formula 1, below, the second carbazole-based compound is represented by Formula 2, below, and the third carbazole-based compound is represented by Formula 3, below: 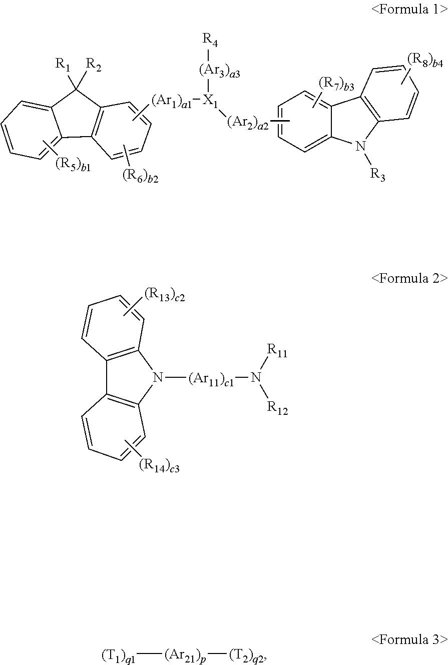
wherein, in Formulae 1 to 3,
X₁ is selected from N, B, or P;
Ar₁ to Ar₃, Ar₁₁, and Ar₂₁ are each independently selected from a substituted or unsubstituted C₃-C₁₀ cycloalkylene group, a substituted or unsubstituted C₂-C₁₀ heterocycloalkylene group, a substituted or unsubstituted C₃-C₁₀ cycloalkenylene group, a substituted or unsubstituted C₂-C₁₀ heterocycloalkenylene group, a substituted or unsubstituted C₆-C₆₀ arylene group, or a substituted or unsubstituted C₂-C₆₀ heteroarylene group;
a1 to a3 and p are each independently an integer of 0 to 5;
c1 is an integer of 1 to 5;
p is an integer of 0 to 5;
R₁, R₂, R₄ to R₈, R₁₃, and R₁₄ are each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁)(Q₂), or —Si(Q₃)(Q₄)(Q₅), wherein Q₁ to Q₅ are each independently selected from a C₁-C₆₀ alkyl group, a C₁-C₆₀ alkoxy group, a C₆-C₆₀ aryl group, or a C₂-C₆₀ heteroaryl group;
R₃, R₁₁, and R₁₂ are each independently selected from a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₂-C₆₀ heteroaryl group, or —Si(Q₃)(Q₄)(Q₅), wherein Q₃ to Q₅ are each independently selected from a C₁-C₆₀ alkyl group, a C₁-C₆₀ alkoxy group, a C₆-C₆₀ aryl group, or a C₂-C₆₀ heteroaryl group;
b1, b4, c2, and c3 are each independently an integer of 1 to 4;
b2 and b3 are each independently an integer of 1 to 3;
T₁ is selected from a substituted or unsubstituted a carbazolyl group, a substituted or unsubstituted azacarbazolyl group, or a substituted or unsubstituted condensed carbazolyl group;
T₂ is an N-containing cyclic group; and
q1 and q2 are each independently an integer of 1 to 5.

10. The organic light-emitting diode as claimed in claim 9, wherein Ar₁ to Ar₃, Ar₁₁, and Ar₂₁ in Formulae 1 to 3 are each independently represented by one of Formulae 10-1 to 10-24 below: 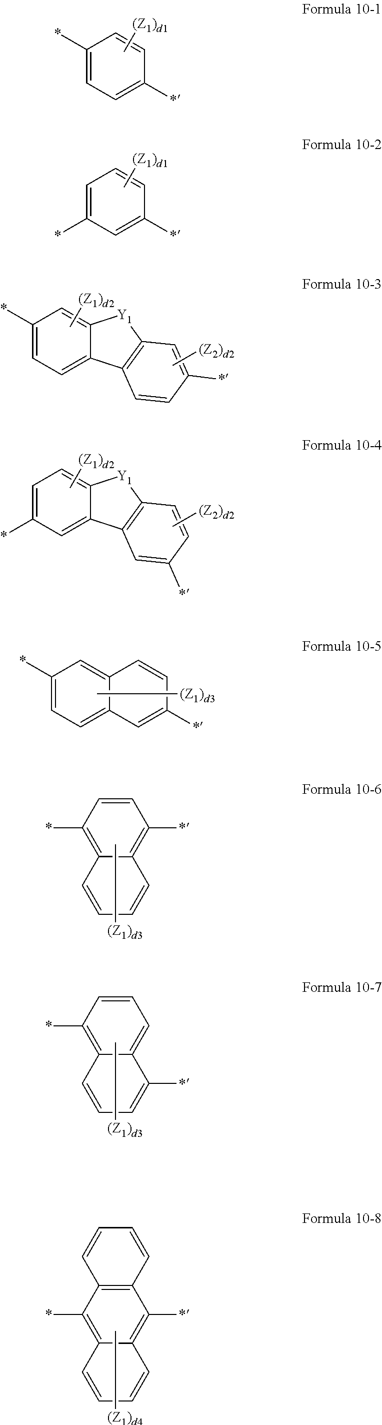 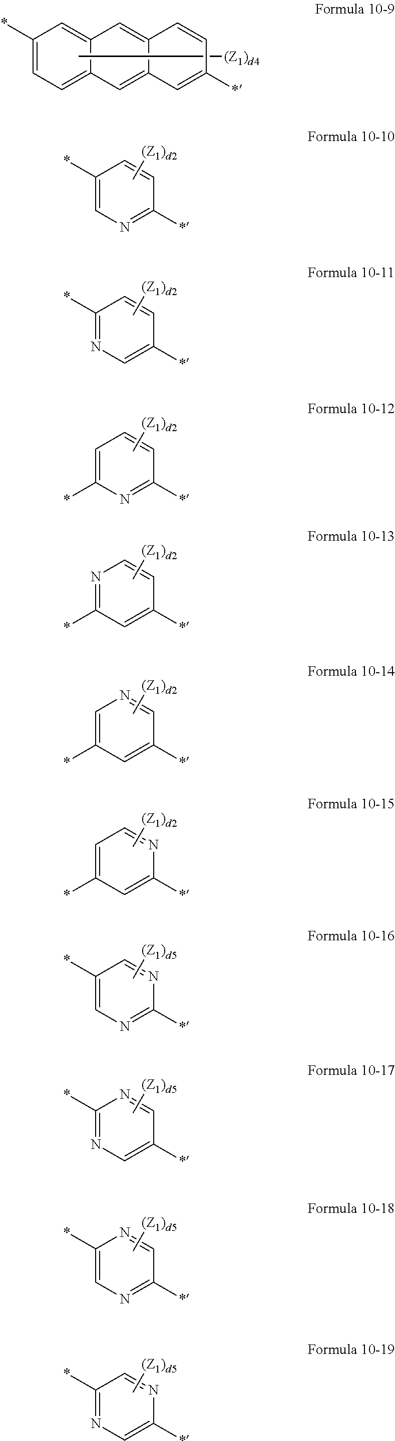 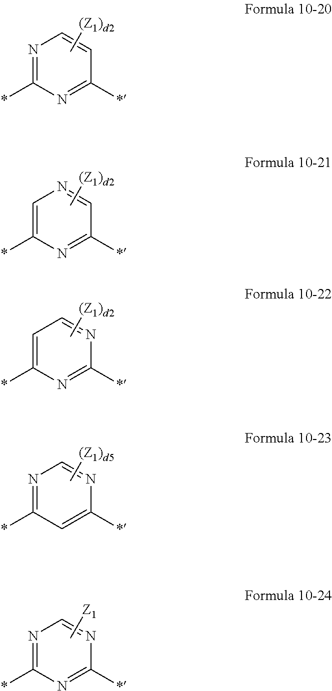
wherein, in Formulae 10-1 to 10-24,
Y₁ is O, S, C(R₂₁)(R₂₂), or N(R₂₃);
Z₁, Z₂, and R₂₁ to R₂₃ are each independently selected from:
a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, and a C₁-C₂₀ alkoxy group;
a C₁-C₂₀ alkyl group and a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;
a C₆-C₂₀ aryl group or a C₂-C₂₀ heteroaryl group;
a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or
—N(Q₁₁)(Q₁₂) or —Si(Q₁₃) (Q₁₄)(Q₁₅), wherein Q₁₁ to Q₁₅ are each independently a C₁-C₂₀ alkyl group, a C₁-C₂₀ alkoxy group, a C₆-C₂₀ aryl group, or a C₂-C₂₀ heteroaryl group,
d1 is an integer of 1 to 4;
d2 is an integer of 1 to 3;
d3 is an integer of 1 to 6;
d4 is an integer of 1 to 8; and
d5 is 1 or 2.

11. The organic light-emitting diode as claimed in claim 9, wherein Ar₁ to Ar₃, Ar₁₁, and Ar₂₁ in Formulae 1 to 3 are each independently represented by one of Formulae 11-1 to 11-11, below:

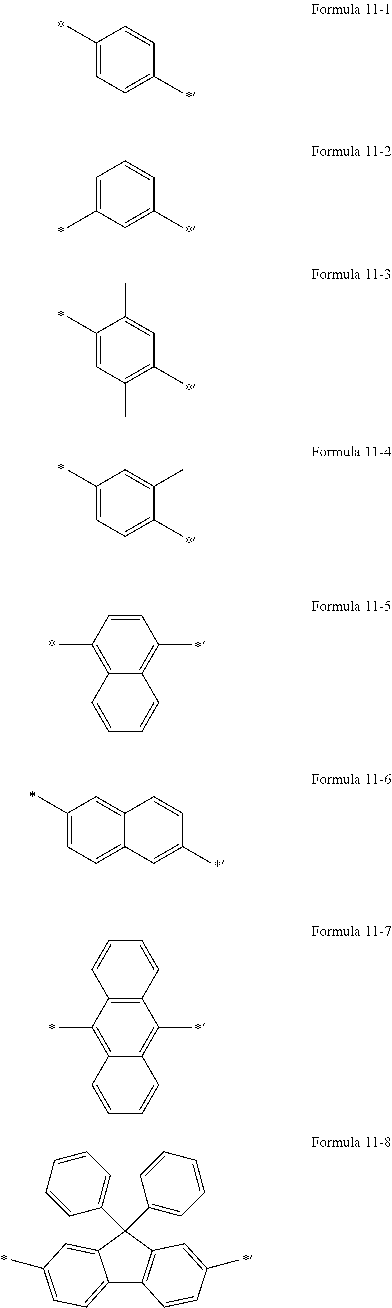

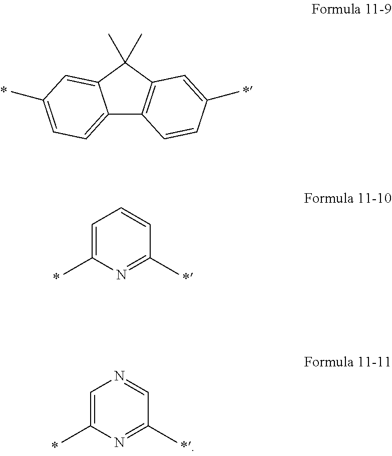

12. The organic light-emitting diode as claimed in claim 9, wherein:
in Formula 1:
i) a1 is 0 and a2 is 0; ii) a1 is 1 and a2 is 0; iii) a1 is 2 and a2 is 0; iv) a1 is 0 and a2 is 1; v) a1 is 0 and a2 is 2; or vi) a1 is 1 and a2 is 1;
in Formula 2, c1 is 1, 2, or 3; and
in Formula 3, p is 0, 1, 2, or 3.

13. The organic light-emitting diode of claim 9, wherein R₃ to R₈ and R₁₁ to R₁₄ in Formulae 1 and 2 are each independently represented by one of Formulae 12-1 to 12-22 below: 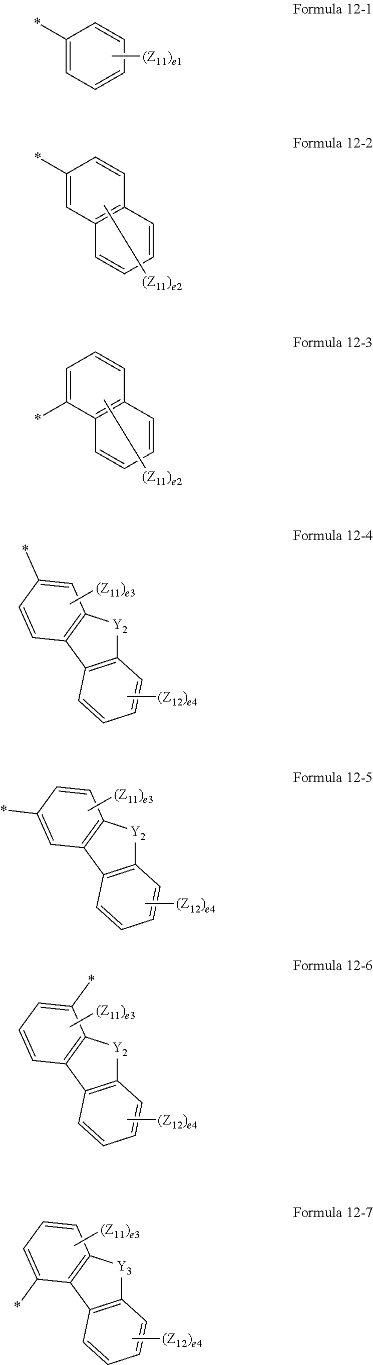 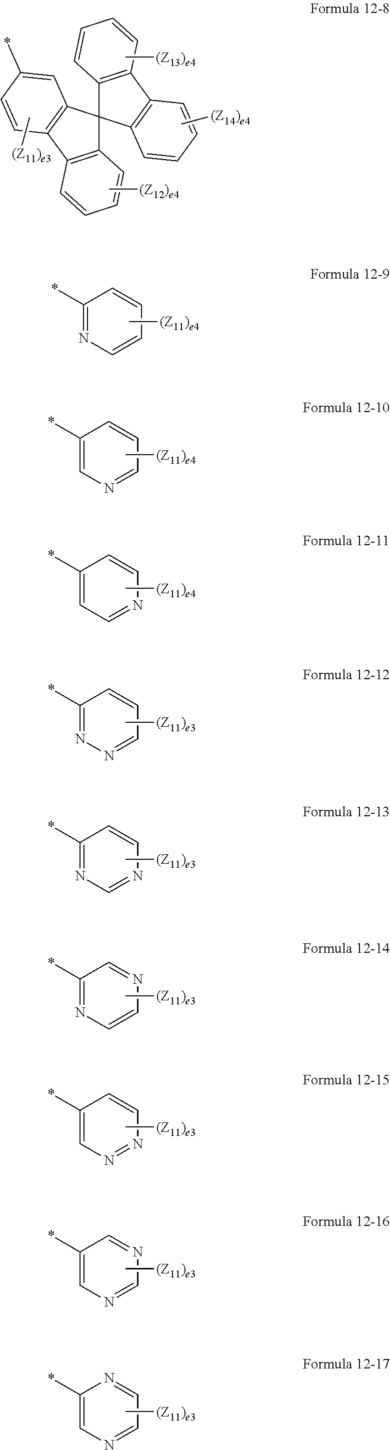 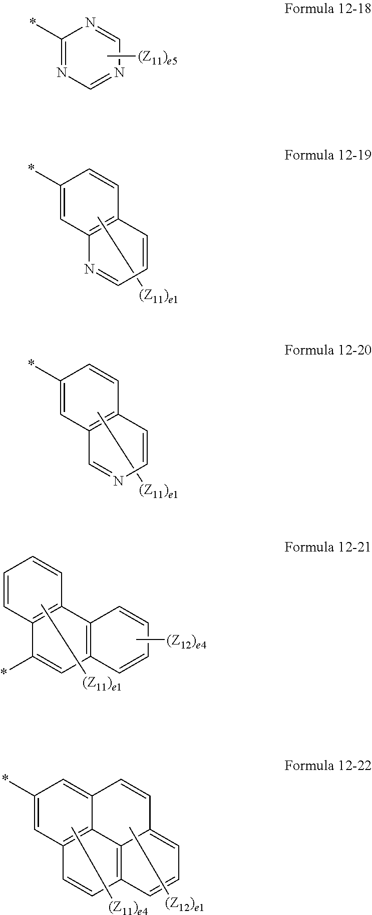
in Formulae 12-1 to 12-22,
Y₂ and Y₃ are each independently selected from O, S, C(R₂₅)(R₂₆), or N(R₂₇);
Z₁₁ to Z₁₄ and R₂₅ to R₂₇ are each independently selected from:
a hydrogen atom, a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;
a C₁-C₂₀ alkyl group or a C₁-C₂₀ alkoxy group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;
a C₆-C₂₀ aryl group or a C₂-C₂₀ heteroaryl group;
a C₆-C₂₀ aryl group or a C₂-C₂₀ heteroaryl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group; or
—N(Q₁₁)(Q₁₂) or —Si(Q₁₃)(Q₁₄)(Q₁₅), wherein Q₁₁ to Q₁₅ are each independently selected from a C₁-C₂₀ alkyl group, a C₁-C₂₀ alkoxy group, a C₆-C₂₀ aryl group, or a C₂-C₂₀ heteroaryl group;
e1 is an integer of 1 to 5;
e2 is an integer of 1 to 7;
e3 is an integer of 1 to 3;
e4 is an integer of 1 to 4; and
e5 is 1 or 2.

14. The organic light-emitting diode of claim 9, wherein R₃ to R₈ and R₁₁ to R₁₄ in Formulae 1 and 2 are each independently represented by one of Formulae 13-1 to 13-19 below: 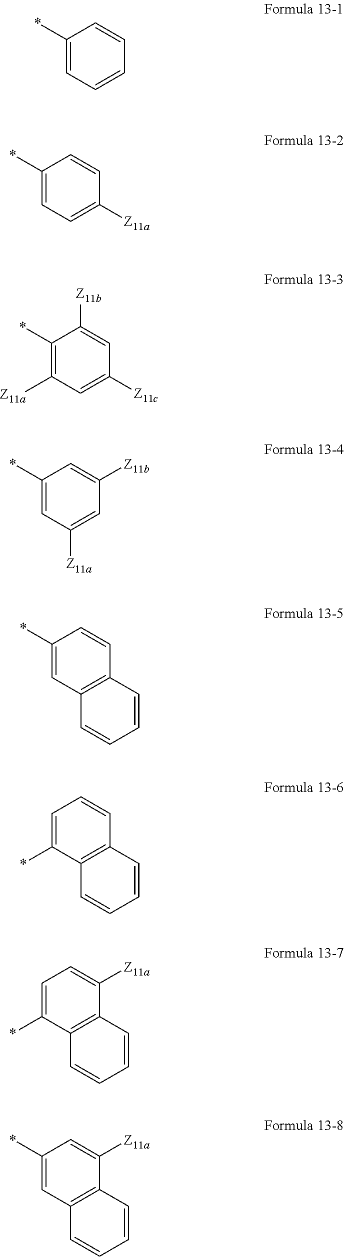 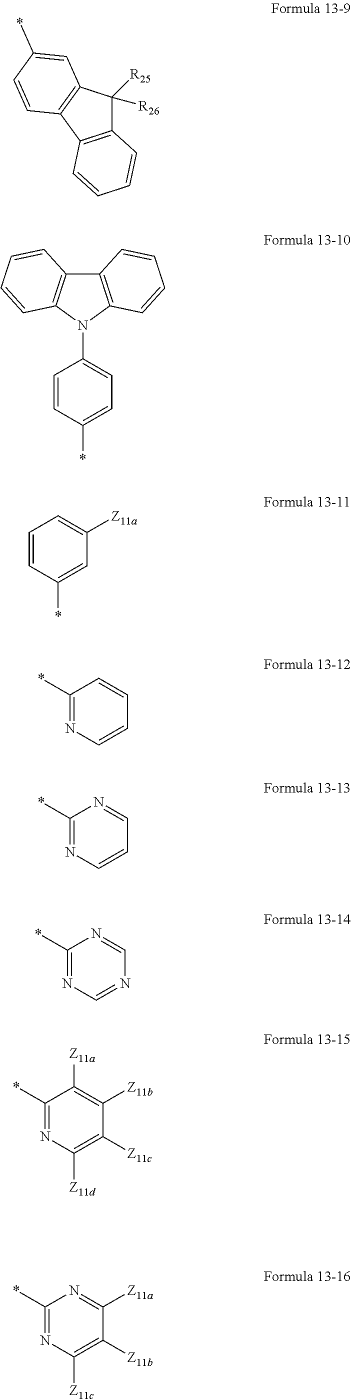 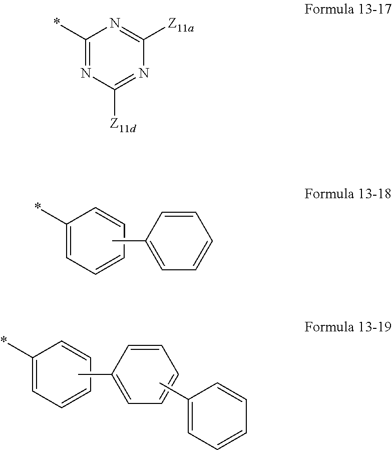
wherein Z₁₁ₐ to Z_{11d}, R₂₅ and R₂₆ in Formulae 13-1 to 13-19 are each independently selected from:
a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, or a C₁-C₂₀ alkoxy group;
a C₁-C₂₀ alkyl group or a C₁-C₂₀ alkoxy group, each substituted with one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;
a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group; or
a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

15. The organic light-emitting diode as claimed in claim 9, wherein R₁ to R₂ in Formula 1 are each independently selected from:
a C₁-C₂₀ alkyl group;
a C₁-C₂₀ alkyl group substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, or a phosphoric acid or a salt thereof;
a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group; or
a phenyl group, a naphthyl group, an anthracenyl group, a fluorenyl group, a carbazolyl group, a pyridinyl group, a pyrimidinyl group, a pyrazinyl group, a pyridazinyl group, a triazinyl group, a quinolinyl group, or an isoquinolinyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

16. The organic light-emitting diode as claimed in claim 9, wherein the first carbazole-based compound represented by Formula 1 is represented by Formula 1A(1) or 1B(1) below:

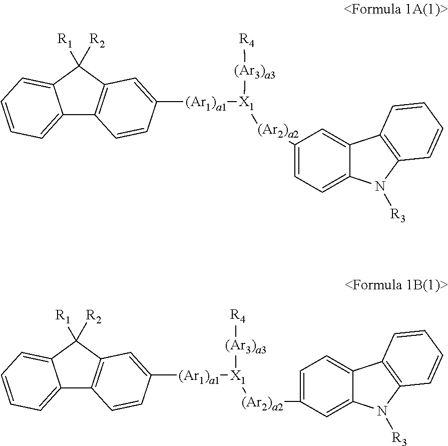

17. The organic light-emitting diode as claimed in claim 9, wherein:
T₁ in Formula 3 is selected from:
a carbazolyl group, an azacarbazolyl group, a benzocarbazolyl group, a naphthocarbazolyl group, or an indolocarbazolyl group; or
a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁₁)(Q₁₂), or —Si(Q₁₃)(Q₁₄)(Q₁₅), wherein Q₁₁ to Q₁₅ are each independently selected from a C₁-C₆₀ alkyl group, a C₁-C₆₀ alkoxy group, a C₆-C₆₀ aryl group, and a C₂-C₆₀ heteroaryl group, and
T₂ in Formula 3 is selected from:
an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group; or
an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthyo group, a substituted or unsubstituted C₂-C₆₀ heteroaryl group, —N(Q₁)(Q₂), or —Si(Q₃)(Q₄)(Q₅), wherein Q₁ to Q₅ are each independently a C₁-C₆₀ alkyl group, a C₁-C₆₀ alkoxy group, a C₆-C₆₀ aryl group, or a C₂-C₆₀ heteroaryl group.

18. The organic light-emitting diode as claimed in claim 9, wherein T₁ in Formula 3 is selected from:
a carbazolyl group, an azacarbazolyl group, a benzocarbazolyl group, a naphthocarbazolyl group, or an indolocarbazolyl group; or
a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.

19. The organic light-emitting diode as claimed in claim 9, wherein T₂ in Formula 3 is selected from:
an imidazolyl group, a triazolyl group, a tetrazolyl group, an oxadiazolyl group, an oxatriazolyl group, a thiatriazolyl group, an imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group; or
an imidazolyl group, a triazolyl group, a tetrazolyl group, an oxadiazolyl group, an oxatriazolyl group, a thiatriazolyl group, n imidazolyl group, a triazolyl group, a pyridinyl group, a pyrimidinyl group, a triazinyl group, a pyrazinyl group, a pyridazinyl group, a furanyl group, a quinolinyl group, an isoquinolinyl group, a quinoxalinyl group, a quinazolinyl group, an acridinyl group, a phenanthrolinyl group, a phenazinyl group, an imidazopyridinyl group, a carbazolyl group, an azacarbazolyl group, a benzocarbazolyl group, a naphthocarbazolyl group, or an indolocarbazolyl group, each substituted with at least one of a deuterium atom, a halogen atom, a hydroxyl group, a cyano group, a nitro group, an amino group, an amidino group, a hydrazine group, a hydrazone group, a carboxyl group or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an anthracenyl group, a fluorenyl group, a dimethylfluorenyl group, a diphenyl fluorenyl group, a carbazolyl group, a phenylcarbazolyl group, a pyridinyl group, a pyrimidinyl group, a pyrazinyl group, a pyridazinyl group, a triazinyl group, a quinolinyl group, or an isoquinolinyl group.
